(19) United States
(12) Patent Application Publication
(10) Pub. No.: US 2025/0351691 A1
(43) Pub. Date: Nov. 13, 2025

(54) DISPLAY DEVICE

(71) Applicant: Samsung Display Co., LTD., Yongin-si (KR)

(72) Inventors: Sun Kwun SON, Yongin-si (KR); Cheol Gon LEE, Yongin-si (KR); Na Hyeon CHA, Yongin-si (KR)

(73) Assignee: Samsung Display Co., LTD., Yongin-si (KR)

(21) Appl. No.: 19/020,041

(22) Filed: Jan. 14, 2025

(30) Foreign Application Priority Data
May 13, 2024 (KR) 10-2024-0062323

(51) Int. Cl. H10K 59/131

(52) U.S. Cl. CPC H10K 59/131

(57) ABSTRACT

A display device comprises a substrate comprising a display area in which emission areas are arranged and a non-display area which is disposed around the display area; a circuit layer disposed on the substrate; and an element layer disposed on the circuit layer and comprising light emitting elements disposed in the emission areas. The circuit layer comprises light-emitting pixel drivers electrically connected to the light emitting elements and arranged in a first direction and a second direction; data lines extending in the second direction and transmitting data signals to the light-emitting pixel drivers; first auxiliary lines extending in the first direction; second auxiliary lines extending in the second direction and neighboring the data lines; and auxiliary connection electrodes disposed between adjacent first auxiliary lines of the first auxiliary lines and spaced apart from the adjacent first auxiliary lines.

### CROSS REFERENCE TO RELATED APPLICATION(S)

This application claims priority to and the benefit of Korean Patent Application No. 10-2024-0062323 under 35 U.S.C. § 119, filed on May 13, 2024 in the Korean Intellectual Property Office, the entire contents of which are incorporated herein by reference.

### BACKGROUND

### 1. Technical Field

The disclosure relates to a display device.

### 2. Description of the Related Art

As the information society develops, demand for display devices that display images is increasing in various forms. For example, display devices are applied to various electronic devices, such as smartphones, digital cameras, notebook computers, navigation devices, and smart televisions.

Display devices may include flat panel display devices, such as liquid crystal display devices, field emission display devices, or light emitting display devices. Light emitting display devices may include an organic light emitting display device including an organic light emitting element, an inorganic light emitting display device including an inorganic light emitting element such as an inorganic semiconductor, and a micro- or nano-light emitting display device including micro- or nano-light emitting elements.

An organic light emitting display device displays an image using light emitting elements, each including a light emitting layer formed from an organic light emitting material. Organic light emitting display devices that use self-light emitting elements may provide improved performance in terms of power consumption, response speed, luminous efficiency, luminance, or wide viewing angles, compared to other display devices.

A display surface of a display device may include a display area where an image is displayed and a non-display area disposed around the display area. In the display area, emission areas that emit light at respective luminances and colors may be arranged.

### SUMMARY

The display device may include light emitting elements disposed in the emission areas and light-emitting pixel drivers electrically connected to the light emitting elements. The light-emitting pixel drivers may supply driving currents to the light emitting elements.

Each of the light-emitting pixel drivers may include a first transistor that generates a driving current and a second transistor electrically connected between a data line, which transmits a data signal, and the first transistor, and may further include transistors for selective electrical connection, initialization, or resetting of some nodes.

In the case where a channel portion of the first transistor includes an oxide semiconductor, a width of the first transistor may be increased beyond a critical value to secure the current characteristics of the first transistor, thereby increasing a width of each of the light-emitting pixel drivers.

Accordingly, there may be a limit to increasing the performance or resolution of the display device.

Aspects of the disclosure may provide a display device which can achieve high resolution by improving the integration density of light-emitting pixel drivers.

According to an aspect of the disclosure, a display device is provided, which may comprise a substrate comprising a display area in which emission areas are arranged and a non-display area disposed around the display area; a circuit layer disposed on the substrate; and an element layer disposed on the circuit layer and that comprises light emitting elements disposed in the emission areas. The circuit layer may comprise light-emitting pixel drivers that are electrically connected to the light emitting elements and are arranged in a first direction and a second direction; data lines that extend in the second direction and transmit data signals to the light-emitting pixel drivers; first auxiliary lines that extend in the first direction; second auxiliary lines that extend in the second direction and neighbor the data lines; and auxiliary connection electrodes disposed between adjacent first auxiliary lines of the first auxiliary lines and spaced apart from the adjacent first auxiliary lines.

The light-emitting pixel drivers may comprise a first light-emitting pixel driver, a second light-emitting pixel driver, a third light-emitting pixel driver, and a fourth light-emitting pixel driver that overlap a first data line of the data lines and are arranged side by side in the second direction; and a fifth light-emitting pixel driver and a sixth light-emitting pixel driver that overlap a second data line of the data lines and are disposed side by side with the first light-emitting pixel driver and the second light-emitting pixel driver in the first direction, and neighbor each other in the second direction. One first auxiliary line of the adjacent first auxiliary lines may overlap the first light-emitting pixel driver and the fifth light-emitting pixel driver, while the other first auxiliary line of the adjacent first auxiliary lines may overlap the second light-emitting pixel driver and the sixth light-emitting pixel driver. The adjacent first auxiliary lines may be adjacent to a boundary between the first light-emitting pixel driver and the second light-emitting pixel driver, and a boundary between the fifth light-emitting pixel driver and the sixth light-emitting pixel driver. One auxiliary connection electrode of the auxiliary connection electrodes may overlap the boundary between the first light-emitting pixel driver and the second light-emitting pixel driver, and another auxiliary connection electrode of the auxiliary connection electrodes may overlap the boundary between the fifth light-emitting pixel driver and the sixth light-emitting pixel driver.

The first data line may comprise a first main extension portion extending in the second direction; a first sub-protruding portion protruding from the first main extension portion, overlapping the first light-emitting pixel driver, and spaced apart from the one auxiliary connection electrode; and a second sub-protruding portion protruding from the first main extension portion, overlapping the second light-emitting pixel driver, and spaced apart from the one auxiliary connection electrode.

The data lines and the second auxiliary lines may be disposed on at least one insulating layer which covers the first auxiliary lines and the auxiliary connection electrodes, and one second auxiliary line of the second auxiliary lines may neighbor the second data line and overlap the fifth light-emitting pixel driver and the sixth light-emitting pixel driver. The one second auxiliary line may comprise a second main extension portion that extends in the second direction; and a third sub-protruding portion that protrudes from the second main extension portion and overlaps the another auxiliary connection electrode. The third sub-protruding portion may be electrically connected to the another auxiliary connection electrode through an auxiliary connection hole.

The circuit layer may further comprise a first auxiliary connection line extending in the second direction from the one first auxiliary line of the adjacent first auxiliary lines and connected to the another auxiliary connection electrode.

The one first auxiliary line may be electrically connected to the one second auxiliary line through the first auxiliary connection line, the another auxiliary connection electrode, and the auxiliary connection hole.

The circuit layer may further comprise data connection electrodes overlapping the first sub-protruding portion and the second sub-protruding portion, the data lines and the second auxiliary lines may be disposed on at least one insulating layer which covers the first auxiliary lines, the auxiliary connection electrodes and the data connection electrodes, and each of the data connection electrodes may be electrically connected to the first data line through an auxiliary data connection hole.

The circuit layer may further comprise a second auxiliary connection line extending in the second direction from the one first auxiliary line of the adjacent first auxiliary lines and connected to one data connection electrode of the data connection electrodes. The one first auxiliary line may be electrically connected to the first data line through the second auxiliary connection line, the one data connection electrode, and the auxiliary data connection hole.

The data lines and the second auxiliary lines may be disposed on at least one insulating layer which covers the first auxiliary lines and the auxiliary connection electrodes, and the auxiliary connection electrodes may be electrically connected to the second auxiliary lines through auxiliary connection holes.

Another adjacent first auxiliary lines of the first auxiliary lines may be disposed adjacent to a boundary between the third light-emitting pixel driver and the fourth light-emitting pixel driver.

The display device may further comprise a display driving circuit which supplies the data signals to the data lines. The circuit layer may further comprise data supply lines disposed in the non-display area and electrically connected between the data lines and the display driving circuit. A bypass area on a side of the display area may comprise a bypass middle area, a first bypass side area disposed side by side with the bypass middle area in the first direction and contacting the non-display area, and a second bypass side area disposed between the bypass middle area and the first bypass side area. The data supply lines may extend to the bypass middle area and the second bypass side area. The first data line may be disposed in the first bypass side area, and the second data line may be disposed in the second bypass side area. The first auxiliary lines may comprise a first bypass auxiliary line electrically connected to the first data line, and first transmission auxiliary lines other than the first bypass auxiliary line. The second auxiliary lines may comprise a second bypass auxiliary line electrically connected to the first bypass auxiliary line and neighboring the second data line, and second transmission auxiliary lines other than the second bypass auxiliary line. A first data supply line which transmits a data signal of the first data line of the data supply lines may be electrically connected to the first data line through the first bypass auxiliary line and the second bypass auxiliary line, and a second data supply line which transmits a data signal of the second data line of the data supply lines may be directly connected and/or electrically connected to the second data line.

The circuit layer may further comprise a first power line that transmits first power to the light-emitting pixel drivers; a second power line that transmits second power to the light emitting elements; a reference voltage line that transmits a reference voltage to the light-emitting pixel drivers; and an initialization voltage line that transmits an initialization voltage to the light-emitting pixel drivers.

Each of the first transmission auxiliary lines and the second transmission auxiliary lines may be electrically connected to one of the first power line, the second power line, the reference voltage line, and the initialization voltage line.

Each of the light-emitting pixel drivers may comprise a first transistor; a second transistor electrically connected between a gate electrode of the first transistor and one data line of the data lines; a third transistor electrically connected between the gate electrode of the first transistor and the reference voltage line; a fourth transistor electrically connected between one light emitting element of the light emitting elements and the initialization voltage line; a fifth transistor electrically connected between a first electrode of the first transistor and the first power line; a sixth transistor electrically connected between a second electrode of the first transistor and the one light emitting element; a first capacitor electrically connected between the gate electrode of the first transistor and the second electrode of the first transistor; and a second capacitor electrically connected between the first power line and the second electrode of the first transistor.

According to another aspect of the disclosure, an electronic device is provided, which may comprise a display device displaying an image, a memory storing an application, a processor executing the application and transmitting an image data signal and an input control signal to the display device, and a power supply module supplying power to the display device. The display device may comprise a substrate comprising a display area in which emission areas are arranged and a non-display area disposed around the display area; a circuit layer disposed on the substrate; and an element layer disposed on the circuit layer and comprising light emitting elements disposed in the emission areas. The circuit layer may comprise light-emitting pixel drivers electrically connected to the light emitting elements and arranged in a first direction and a second direction; data lines extending in the second direction and transmitting data signals to the light-emitting pixel drivers; first bypass auxiliary lines extending in the first direction and electrically connected to first data lines adjacent to the non-display area in the first direction of the data lines; second bypass auxiliary lines extending in the second direction, neighboring second data lines spaced farther from the non-display area than the first data lines in the first direction of the data lines, and electrically connected to the first bypass auxiliary lines; and auxiliary connection electrodes disposed between two first bypass auxiliary lines adjacent to each other in the second direction of the first bypass auxiliary lines and spaced apart from the two first bypass auxiliary lines.

The display device may further comprise a display driving circuit which supplies data signals to the data lines. The circuit layer may further comprise data supply lines disposed in the non-display area and electrically connected between the data lines and the display driving circuit. A bypass area on a side of the display area may comprise a bypass middle area, a first bypass side area disposed side by side with the bypass middle area in the first direction and contacting the non-display area, and a second bypass side area disposed between the bypass middle area and the first bypass side area. The data supply lines may extend to the bypass middle area and the second bypass side area. The first data lines may be disposed in the first bypass side area, and the second data lines and the second bypass auxiliary lines may be disposed in the second bypass side area. The first data supply lines, which transmit data signals of the first data lines of the data supply lines, may be electrically connected to the first data lines through the first bypass auxiliary lines and the second bypass auxiliary lines, and second data supply lines, which transmit data signals of the second data lines of the data supply lines, may be directly connected and/or electrically connected to the second data lines,

The light-emitting pixel drivers may comprise a first light-emitting pixel driver, a second light-emitting pixel driver, a third light-emitting pixel driver, and a fourth light-emitting pixel driver, disposed in the first bypass side area, overlapping one first data line of the first data lines, and arranged side by side in the second direction. A fifth light-emitting pixel driver and a sixth light-emitting pixel driver may be disposed in the second bypass side area, overlapping one second data line of the second data lines and one second bypass auxiliary line of the second bypass auxiliary lines, and neighboring each other in the second direction. The fifth light-emitting pixel driver and the sixth light-emitting pixel driver may be disposed side by side with the first light-emitting pixel driver and the second light-emitting pixel driver in the first direction. One first bypass auxiliary line of the first bypass auxiliary lines may overlap the first light-emitting pixel driver and the fifth light-emitting pixel driver, while another first bypass auxiliary line of the two first bypass auxiliary lines may overlap the second light-emitting pixel driver and the sixth light-emitting pixel driver. The first bypass auxiliary lines may be adjacent to a boundary between the first light-emitting pixel driver and the second light-emitting pixel driver and a boundary between the fifth light-emitting pixel driver and the sixth light-emitting pixel driver. One auxiliary connection electrode of the auxiliary connection electrodes may overlap the boundary between the first light-emitting pixel driver and the second light-emitting pixel driver, and another auxiliary connection electrode of the auxiliary connection electrodes may overlap the boundary between the fifth light-emitting pixel driver and the sixth light-emitting pixel driver.

The data lines and the second bypass auxiliary lines may be disposed on at least one insulating layer which covers the first auxiliary lines. The one first data line may comprise a first main extension portion extending in the second direction, a first sub-protruding portion protruding from the first main extension portion, overlapping the first light-emitting pixel driver and spaced apart from the one auxiliary connection electrode, and a second sub-protruding portion protruding from the first main extension portion, overlapping the second light-emitting pixel driver and spaced apart from the same auxiliary connection electrode. The second bypass auxiliary line may comprise a second main extension portion extending in the second direction and a third sub-protruding portion protruding from the second main extension portion and overlapping another auxiliary connection electrode. The third sub-protruding portion may be electrically connected to another auxiliary connection electrode through an auxiliary connection hole.

The circuit layer may further comprise a first auxiliary connection line extending in the second direction from the one first bypass auxiliary line of the two first bypass auxiliary lines and connected to another auxiliary connection electrode. The one first bypass auxiliary line may be electrically connected to the one second bypass auxiliary line through the first auxiliary connection line, the another auxiliary connection electrode, and the auxiliary connection hole.

The circuit layer may further comprise data connection electrodes overlapping the first sub-protruding portion and the second sub-protruding portion and electrically connected to the one first data line through an auxiliary data connection hole; and a second auxiliary connection line extending from the one first bypass auxiliary line in the second direction and connected to one data connection electrode of the data connection electrodes. The one first bypass auxiliary line may be electrically connected to the one first data line through the second auxiliary connection line, the one data connection electrode, and the auxiliary data connection hole.

### BRIEF DESCRIPTION OF THE DRAWINGS

These and other aspects, features, and advantages of embodiments will become more apparent and readily appreciated from the following description taken in conjunction with the accompanying drawings, in which:

FIG. 1 is a schematic perspective view of a display device according to embodiments;

FIG. 2 is a schematic plan view of the display device of FIG. 1;

FIG. 3 is a schematic cross-sectional view taken along line A-A′ of FIG. 2;

FIG. 4 is a schematic layout view of part B of FIG. 2;

FIG. 5 is a schematic equivalent circuit diagram of a light-emitting pixel driver of FIG. 4 according to embodiments;

FIG. 6 is a schematic cross-sectional view illustrating a first transistor, a second transistor, a sixth transistor, a first capacitor, a second capacitor, and a light emitting element of FIG. 5;

FIG. 7 is a schematic plan view of a substrate of FIG. 3 according to embodiments;

FIG. 8 is a schematic layout view of a circuit layer in part C of FIG. 7;

FIG. 9 is a schematic layout view of the circuit layer in part D of FIG. 7;

FIG. 10 is a schematic plan view of part E of FIG. 8 according to an embodiment;

FIG. 11 is a schematic cross-sectional view taken along line G-G′ of FIG. 10;

FIG. 12 is a schematic plan view of part F of FIG. 9 according to an embodiment;

FIG. 13 is a schematic plan view of part E of FIG. 8 according to an embodiment;

FIG. 14 is a schematic plan view of part F of FIG. 9 according to an embodiment;

FIG. 15 is a block diagram of an electronic device according to an embodiment; and

FIG. 16 is a schematic diagram of an electronic device according to embodiments.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art. Various embodiments do not have to be exclusive nor limit the disclosure. For example, specific shapes, configurations, and characteristics of an embodiment may be used or implemented in another embodiment.

In the drawings, sizes, thicknesses, ratios, and dimensions of the elements may be exaggerated for ease of description and for clarity. Like reference numbers and/or reference characters refer to like elements throughout.

Some of the parts which are not associated with the description may be omitted in order to describe embodiments of the disclosure.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

In the case where an element, such as a layer, a region, a portion, or the like, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

The phrase “in a plan view” refers to viewing an object portion from above, and the phrase “in a schematic cross-sectional view” refers to viewing a schematic cross-section taken by vertically cutting an object portion and viewing it from the side. The terms “overlap” or “overlapped” mean that a first object may be above, below, or to a side of a second object, and vice versa. Additionally, the term “overlap” may include meanings such as layering, stacking, facing, extending over, covering, or partly covering, as would be understood by those of ordinary skill in the art. The expression “not overlap” may include meaning such as “apart from,” “set aside from,” or “offset from,” and any other suitable equivalents as would be appreciated by those of ordinary skill in the art. The terms “face” and “facing” may indicate that a first object may directly or indirectly oppose a second object. In a case where a third object intervenes between a first and second object, the first and second objects may still be considered to be indirectly opposing and facing each other.

Spatially relative terms, such as “beneath,” “below,” “under,” “lower,” “on,” “above,” “upper,” “over,” “higher,” “side” (e.g., as in “sidewall”), and the like, may be used herein for descriptive purposes, and, thereby, to describe one element or feature's relationship to another clement(s) or feature(s), as illustrated in the drawings. Spatially relative terms are intended to encompass different orientations of an apparatus in use, operation, and/or manufacture in addition to the orientation depicted in the drawings. For example, if the device in the drawings is turned over, elements described as “below” or “beneath” other elements or features would then be oriented “above” the other elements or features. Thus, the term “below” can encompass both an orientation of above and below. Furthermore, the device may be otherwise oriented (e.g., rotated 90 degrees or at other orientations), and, as such, the spatially relative descriptors used herein should interpreted accordingly.

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

It will be understood that although the terms “first,” “second,” “third,” or the like may be used herein to describe various elements, these elements should not be limited by these terms. These terms are only used to distinguish one element from another for convenience of description and explanation. For example, “a first element” may be referred to as “a second element” or “a third element,” and similarly, “a second element” or “a third element” may be referred to as “a first element” without departing from the scope of the disclosure.

As used herein, the singular forms “a,” “an,” and “the” are intended to include the plural forms as well, unless the context clearly indicates otherwise.

The term “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an idealized or excessively formal sense unless clearly defined in the specification.

Hereinafter, embodiments will be described with reference to the accompanying drawings.

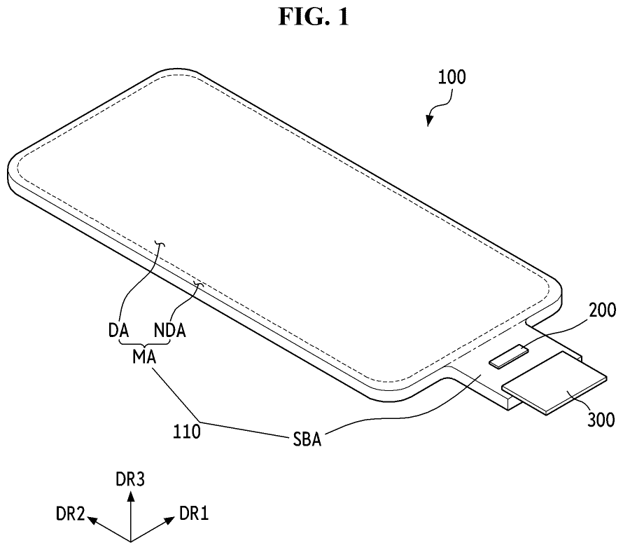

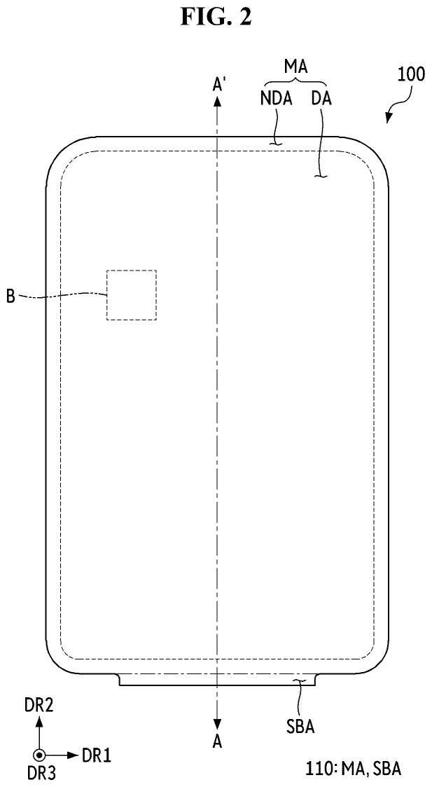

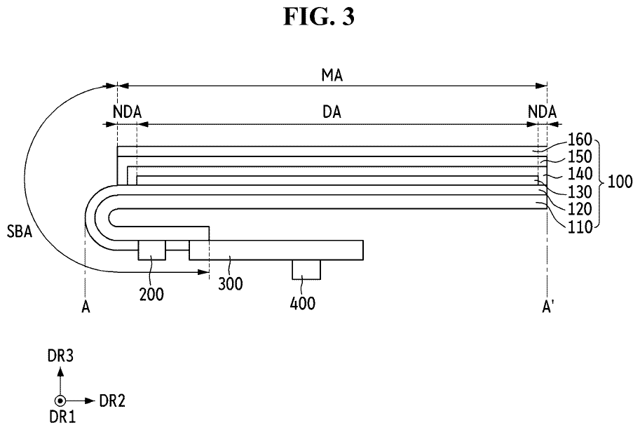

FIG. 1 is a schematic perspective view of a display device 100 according to embodiments. FIG. 2 is a schematic plan view of the display device 100 in FIG. 1. FIG. 3 is a schematic cross-sectional view taken along line A-A′ of FIG. 2.

Referring to FIGS. 1 and 2, the display device 100 may display moving images or still images. The display device 100 may be used as a display screen in portable electronic devices such as mobile phones, smartphones, tablet personal computers (PCs), smart watches, watch phones, mobile communication terminals, electronic notebooks, electronic books, portable multimedia players (PMPs), navigation devices, and ultra-mobile PCs (UMPCs), as well as in various products such as televisions, notebook computers, monitors, billboards, and Internet of things (IoT) devices.

The display device 100 may be a light emitting display device such as an organic light emitting display device using an organic light emitting diode, a quantum dot light emitting display device including a quantum dot light emitting layer, an inorganic light emitting display device including an inorganic semiconductor, or a micro- or nano-light emitting display device using a micro- or nano-light emitting diode. For example, a case where the display device 100 is an organic light emitting display device will be described below. However, this disclosure is not limited thereto and may also apply to display devices including an organic insulating material, an organic light emitting material, or a metal material.

The display device 100 may be flat, but this disclosure is not limited thereto. For example, the display device 100 may include a curved portion at left and right ends, with a constant or varying curvature. the display device 100 may be flexible so that it can be curved, bent, folded, or rolled.

As illustrated in FIGS. 1 through 3, the display device 100 includes a substrate 110.

The substrate 110 may include a main area MA corresponding to a display surface of the display device 100 and a sub-area SBA protruding from a side of the main area MA.

As illustrated in FIG. 2, the main area MA may include a display area DA disposed in the central region and a non-display area NDA disposed around the display area DA.

The display area DA may be shaped like a rectangular plane having short sides in a first direction DR1 and long sides in a second direction DR2 intersecting the first direction DR1. Each corner, where a short side extending in the first direction DR1 meets a long side extending in the second direction DR2, may be rounded to have a selected curvature or may be right-angled. The planar shape of the display area DA is not limited to a quadrilateral shape but may also be other polygonal shapes, a circular shape, or an oval shape.

The non-display area NDA may be disposed at edges of the main area MA and may surround the display area DA.

The sub-area SBA may extend in the second direction DR2 from a portion of a side of the main area MA that extends in the first direction DR1.

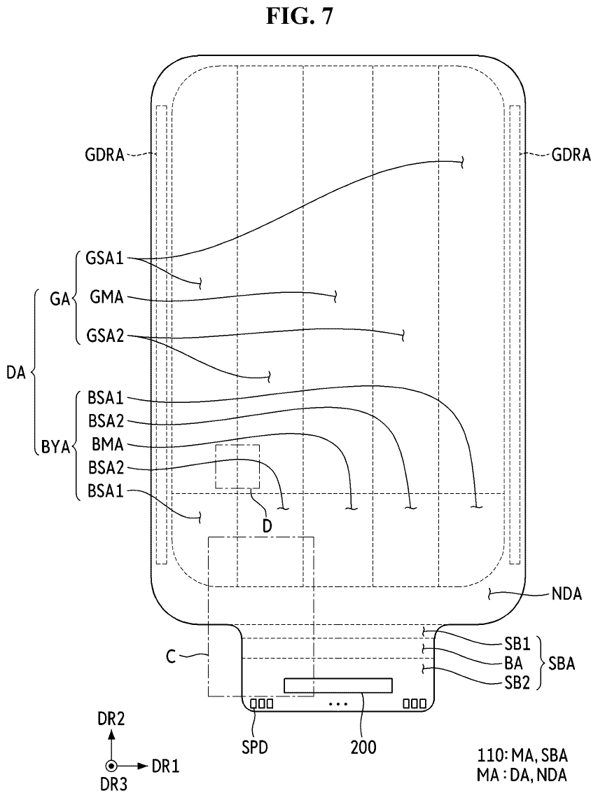

The sub-area SBA may include a bending area BA (see FIG. 7) that is transformed into a bent shape.

FIGS. 2 and 3 illustrate the display device 100 with a portion of the sub-area SBA bent.

The sub-area SBA may include the bending area BA transformed into a bent shape, a first sub-area SB1 (see FIG. 7) disposed between a side of the main area MA and a side of the bending area BA, and a second sub-area SB2 (see FIG. 7) extending from the other side of the bending area BA.

As illustrated in FIG. 3, in the case where the bending area BA is bent, the second sub-area SB2 may be placed on a back surface of the display device 100 and may overlap the main area MA.

A display driving circuit 200, provided as an integrated circuit chip, may be mounted in the second sub-area SB2.

A circuit board 300 may be bonded to a side of the second sub-area SB2.

A touch driving circuit 400, provided as an integrated circuit chip, may be mounted on the circuit board 300.

Referring to FIG. 3, the display device 100 according to the embodiments includes the substrate 110, a circuit layer 120 disposed on the substrate 110, and an element layer 130 disposed on the circuit layer 120.

The display device 100 according to the embodiments may further include a sealing layer 140 disposed on the element layer 130 and a touch sensor layer 150 disposed on the sealing layer 140. The display device 100 according to the embodiments may further include a polarization layer 160 disposed on the touch sensor layer 150 to reduce reflection of external light.

The substrate 110 may be made of an insulating material such as polymer resin. For example, the substrate 110 may be made of polyimide. The substrate 110 may be a flexible substrate that can be bent, folded, or rolled.

In another embodiment, the substrate 110 may be made of an insulating material such as glass.

The substrate 110 may include the main area MA and the sub-area SBA. The main area MA may include the display area DA and the non-display area NDA.

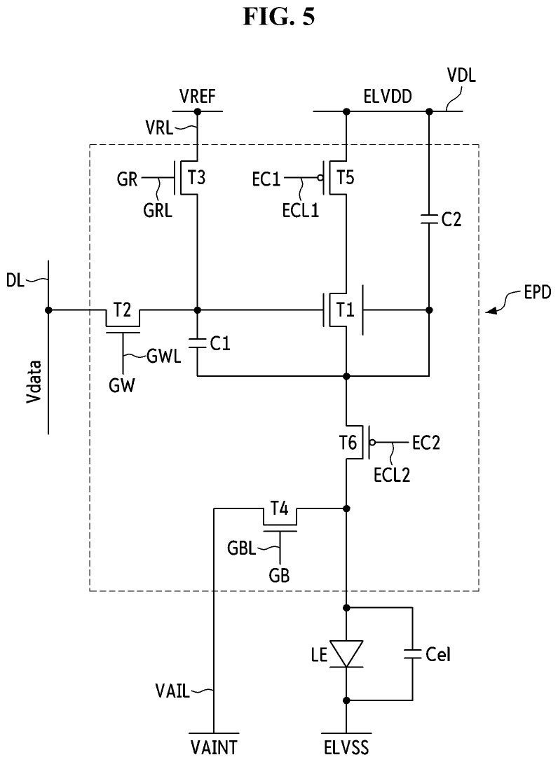

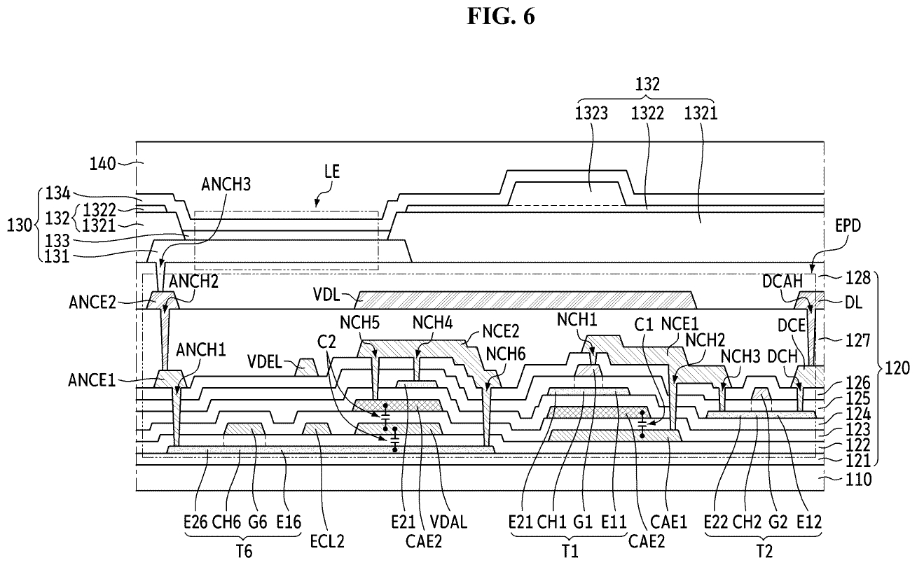

The element layer 130 may include light emitting elements LE (see FIGS. 5 and 6) disposed in emission areas EA.

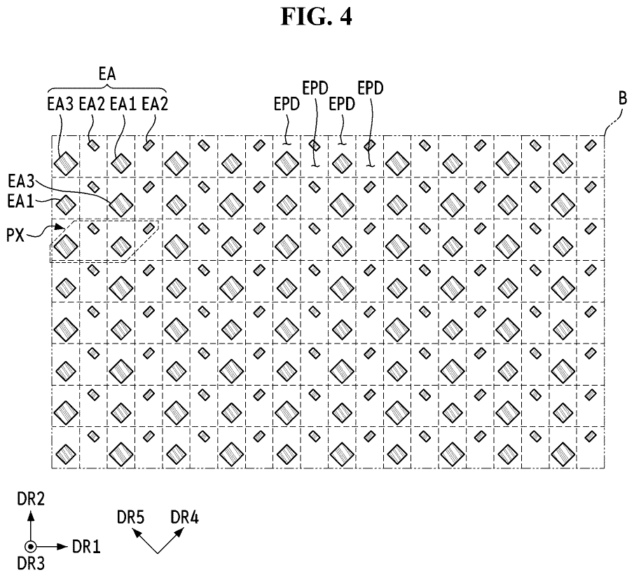

The circuit layer 120 may include light-emitting pixel drivers EPD (see FIG. 4) electrically connected to the light emitting elements LE of the element layer 130.

The sealing layer 140 may be disposed on the element layer 130 and may have a structure in which at least one organic layer is interposed between two or more inorganic layers.

The touch sensor layer 150 may include touch electrodes for sensing a point in the main area MA where a touch of a person or an object has occurred by detecting a signal that varies according to the touch of the person or the object.

The polarization layer 160 may prevent the deterioration of the visibility of an image due to the reflection of external light by blocking the external light reflected from the touch sensor layer 150, the sealing layer 140, the element layer 130, the circuit layer 120, and their interfaces.

According to embodiments, the display device 100 may further include the display driving circuit 200, provided as an integrated circuit chip, mounted on the sub-area SBA of the substrate 110.

The display driving circuit 200 may supply data signals Vdata (see FIG. 5) to data lines DL (see FIGS. 5 and 6) of the circuit layer 120.

According to embodiments, the display device 100 may further include the circuit board 300 bonded to the sub-area SBA of the substrate 110. The circuit board 300 may be bonded to pads disposed on the sub-area SBA of the substrate 110 using a low-resistance, high-reliability material such as an anisotropic conductive film or SAP.

The touch driving circuit 400 may be mounted on the circuit board 300.

In the case where the touch sensor layer 150 includes capacitive touch electrodes and sensing electrodes, the touch driving circuit 400 may detect a touch based on capacitance changes. However, this is merely an example, and the touch sensor layer 150 and the touch driving circuit 400 of FIG. 3 may use a touch sensing method other than the capacitive method.

FIG. 4 is a schematic layout view of part B of FIG. 2.

Referring to FIG. 4, the display area DA of the display device 100 according to the embodiments may include emission areas EA. The display area DA may further include a non-emission area disposed between the emission areas EA.

Light-emitting pixel drivers EPD respectively corresponding to the emission areas EA may be disposed side by side in the first direction DR1 and the second direction DR2 in the display area DA. The light-emitting pixel drivers EPD may be electrically connected to the light emitting elements LE (see FIGS. 5 and 6) of the element layer 130 disposed in the emission areas EA, respectively.

The emission areas EA may have a rhombic planar shape or a rectangular planar shape. However, this is merely an example, and the planar shape of the emission areas EA according to an embodiment is not limited to that illustrated in FIG. 4. For example, the emission areas EA may also have a polygonal shape such as a quadrilateral, a pentagon, or a hexagon, or may have a circular or oval planar shape including curved edges.

The emission areas EA may include first emission areas EA1 emitting light in a first wavelength band, second emission areas EA2 emitting light in a second wavelength band lower than the first wavelength band, and third emission areas EA3 emitting light in a third wavelength band lower than the second wavelength band.

For example, the first wavelength band may correspond to red and range from about 600 to about 750 nm. The second wavelength band may correspond to green and range from about 480 to about 560 nm. The third wavelength band may correspond to blue and range from about 370 to about 460 nm.

The first emission areas EA1 and the third emission areas EA3 may be alternately arranged in the first direction DR1 or the second direction DR2.

The second emission areas EA2 may be arranged side by side with each other in the first direction DR1 or the second direction DR2.

The second emission areas EA2 may neighbor the first emission areas EA1 and the third emission areas EA3 in diagonal directions DR4 and DR5 intersecting the first direction DR1 and the second direction DR2.

Among these emission areas EA, the first emission areas EA1, the second emission areas EA2, and the third emission areas EA3 adjacent to each other may form pixels PX which display their respective luminances and colors.

For example, each of the pixels PX may be a basic unit that displays various colors, including white, at a selected luminance level.

Each of the pixels PX may include at least one first emission area EA1, at least one second emission area EA2, and at least one third emission area EA3 adjacent to each other. Therefore, each of the pixels PX can display various colors through mixing of light emitted from the first through third emission areas EA1 through EA3 adjacent to each other.

FIG. 5 is a schematic equivalent circuit diagram of a light-emitting pixel driver EPD in FIG. 4, according to embodiments.

Referring to FIG. 5, the circuit layer 120 (see FIG. 3) may include a first power line VDL which transmits first power ELVDD to the light-emitting pixel drivers EPD, a second power line which transmits second power ELVSS to the light emitting elements LE, a reference voltage line VRL which transmits a reference voltage VREF to the light-emitting pixel drivers EPD, and an initialization voltage line VAIL which transmits an initialization voltage VAINT.

The light emitting elements LE of the element layer 130 (see FIG. 3) may be electrically connected between the light-emitting pixel drivers EPD and the second power ELVSS.

For example, one of the light emitting elements LE may be electrically connected between one of the light-emitting pixel drivers EPD of the circuit layer 120 and the second power ELVSS.

The second power ELVSS may be at a lower voltage level than the first power ELVDD.

For example, an anode of a light emitting element LE may be electrically connected to a light-emitting pixel driver EPD, and the second power ELVSS having a lower voltage level than first power ELVDD may be applied to a cathode of the light emitting element LE.

A capacitor Cel connected in parallel to the light emitting element LE may be a parasitic capacitance between the anode and the cathode.

The circuit layer 120 may include a scan write line GWL which transmits a scan write signal GW, a reset control line GRL which transmits a reset control signal GR, a bias control line GBL which transmits a bias control signal GB, a first emission control line ECL1 which transmits a first emission control signal EC1, and a second emission control line ECL2 which transmits a second emission control signal EC2.

A light-emitting pixel driver EPD of the circuit layer 120 may include a first transistor T1 generating a driving current for driving the light emitting element LE, two or more transistors T2 through T6 electrically connected to the first transistor T1, and one or more capacitors C1 and C2.

A second transistor T2 may be electrically connected between a gate electrode of the first transistor T1 and a data line DL.

The second transistor T2 may be turned on by the scan write signal GW of the scan write line GWL.

In the case where the second transistor T2 is turned on, a data signal Vdata from the data line DL may be transmitted to the gate electrode of the first transistor T1.

In the case where a voltage difference between the gate electrode of the first transistor T1 and a second electrode of the first transistor T1 becomes greater than a threshold voltage of the first transistor T1 due to the data signal Vdata transmitted to the gate electrode of the first transistor T1, the first transistor T1 may be turned on. Accordingly, a drain-source current of the first transistor T1 may be generated in proportion to the data signal Vdata.

A third transistor T3 may be electrically connected between the gate electrode of the first transistor T1 and the reference voltage line VRL.

The third transistor T3 may be turned on by the reset control signal GR of the reset control line GRL.

In the case where the third transistor T3 is turned on, the electric potential of the gate electrode of the first transistor T1 may be reset to the reference voltage VREF of the reference voltage line VRL.

A fourth transistor T4 may be electrically connected between the light emitting element LE and the initialization voltage line VAIL.

The fourth transistor T4 may be turned on by the bias control signal GB of the bias control line GBL.

In the case where the fourth transistor T4 is turned on, the electric potential of the anode of the light emitting element LE may be initialized to the initialization voltage VAINT of the initialization voltage line VAIL.

A fifth transistor T5 may be electrically connected between a first electrode of the first transistor T1 and the first power line VDL.

The fifth transistor T5 may be turned on by the first emission control signal EC1 of the first emission control line ECL1.

In the case where the fifth transistor T5 is turned on, the first power ELVDD of the first power line VDL may be transmitted to the first electrode of the first transistor T1.

A sixth transistor T6 may be electrically connected between the second electrode of the first transistor T1 and the light emitting element LE.

The sixth transistor T6 may be turned on by the second emission control signal EC2 of the second emission control line ECL2.

In the case where the sixth transistor T6 is turned on, the drain-source current of the first transistor T1, generated in proportion to the data signal Vdata, may be transmitted to the light emitting element LE through the sixth transistor T6.

Accordingly, the light emitting element LE may emit light at a luminance level corresponding to the data signal Vdata.

A first capacitor C1 may be electrically connected between the gate electrode of the first transistor T1 and the second electrode of the first transistor T1.

Accordingly, the first capacitor C1 may be charged with the data signal Vdata transmitted to the gate electrode of the first transistor T1, and the first transistor T1 may be kept turned on for a selected period of time by a voltage charged in the first capacitor C1.

A second capacitor C2 may be electrically connected between the second electrode of the first transistor T1 and the first power line VDL.

The voltage of the first capacitor C1, corresponding to a potential difference between the gate electrode of the first transistor T1 and the second electrode of the first transistor T1, may vary based on the data signal Vdata, and may be divided by the second capacitor C2. Accordingly, the threshold voltage of the first transistor T1 can be compensated.

According to embodiments, the first transistor T1 may include the gate electrode and an auxiliary gate electrode facing each other on both sides of a channel portion.

The gate electrode of the first transistor T1 may be electrically connected to the second transistor T2.

The auxiliary gate electrode of the first transistor T1 may be electrically connected to the second electrode of the first transistor T1.

Accordingly, when the first transistor T1 is turned on by the data signal Vdata transmitted to the gate electrode of the first transistor T1, a portion of the channel portion of the first transistor T1 which is adjacent to the auxiliary gate electrode may not be activated, unlike a portion of the channel portion of the first transistor T1 which is adjacent to the gate electrode.

Therefore, since the electron mobility of the channel portion of the first transistor T1 is reduced, the slope of a current curve representing the relationship between the voltage of the gate electrode of the first transistor T1 and the source-drain current may become more gradual. Accordingly, the driving voltage range of the first transistor T1 may be widened, thereby improving the ease of luminance control.

As illustrated in FIG. 5, the first transistor T1 may be an N-type MOSFET. At least some of the second through sixth transistors T2 through T6 may be P-type MOSFETs. For example, the fifth transistor T5 and the sixth transistor T6 may be P-type MOSFETs, and the second transistor T2, the third transistor T3 and the fourth transistor T4 may be N-type MOSFETs.

Accordingly, according to embodiments, the circuit layer 120 may include a first semiconductor layer (e.g., CH6, E16 and E26 of FIG. 6) for providing P-type MOSFETs and a second semiconductor layer (e.g., CH1, E11, E21, CH2, E12 and E22 of FIG. 6) for providing N-type MOSFETs.

FIG. 6 is a schematic cross-sectional view illustrating the first transistor T1, the second transistor T2, the sixth transistor T6, the first capacitor C1, the second capacitor C2, and the light emitting element LE of FIG. 5.

Referring to FIG. 6, the display device 100 according to the embodiments may include the substrate 110, the circuit layer 120 on the substrate 110, and the element layer 130 on the circuit layer 120.

The display device 100 may further include the sealing layer 140 on the element layer 130.

According to embodiments, the circuit layer 120 may include the first semiconductor layer (e.g., CH6, E16 and E26) disposed on the substrate 110, a first gate insulating layer 122 covering the first semiconductor layer (e.g., CH6, E16 and E26), a first gate conductive layer (e.g., G6, ECL2, VDAL and CAE1) disposed on the first gate insulating layer 122, a second gate insulating layer 123 covering the first gate conductive layer (e.g., G6, ECL2, VDAL and CAE1), a second gate conductive layer (e.g., VDAL and CAE2) disposed on the second gate insulating layer 123, a first interlayer insulating layer 124 covering the second gate conductive layer (e.g., VDAL and CAE2), the second semiconductor layer (e.g., CH1, E11, E21, CH2, E12 and E22) disposed on the first interlayer insulating layer 124, a third gate insulating layer 125 covering the second semiconductor layer (e.g., CH1, E11, E21, CH2, E12 and E22), a third gate conductive layer (e.g., G1 and G2) disposed on the third gate insulating layer 125, a second interlayer insulating layer 126 covering the third gate conductive layer (e.g., G1 and G2), a first source-drain conductive layer (e.g., ANCE1, VDEL, NCE1, NCE2 and DCE) disposed on the second interlayer insulating layer 126, a first planarization layer 127 covering the first source-drain conductive layer (e.g., ANCE1, VDEL, NCE1, NCE2 and DCE), a second source-drain conductive layer (e.g., ANCE2, VDL and DL) disposed on the first planarization layer 127, and a second planarization layer 128 covering the second source-drain conductive layer (e.g., ANCE2, VDL and DL).

According to embodiments, the circuit layer 120 may further include a buffer layer 121 covering the substrate 110. The first semiconductor layer (e.g., CH6, E16 and E26) may be disposed on the buffer layer 121.

As described above with reference to FIG. 5, the light-emitting pixel driver EPD may include the first transistor T1 and two or more transistors T2 through T6 electrically connected to the first transistor T1.

The first through fourth transistors T1 through T4 may be N-type MOSFETs, and the fifth and sixth transistors T5 and T6 may be P-type MOSFETs.

Each of the fifth and sixth transistors T5 and T6, provided as P-type MOSFETs, may include a channel portion, a first electrode, and a second electrode disposed in the first semiconductor layer, with a gate electrode disposed in the first gate conductive layer and overlapping the channel portion.

For example, the first semiconductor layer may include a silicon semiconductor material such as polysilicon or amorphous silicon.

For example, the sixth transistor T6 may include a channel portion CH6 disposed in the first semiconductor layer, a first electrode E16 disposed in the first semiconductor layer and connected to a side of the channel portion CH6, a second electrode E26 disposed in the first semiconductor layer and connected to the other side of the channel portion CH6, and a gate electrode G6 disposed in the first gate conductive layer and overlapping the channel portion CH6.

The fifth transistor T5 may be a P-type MOSFET identical to the sixth transistor T6, and thus a redundant description thereof will be omitted below.

Each of the first through fourth transistors T1 through T4, provided as N-type MOSFETs, may include a channel portion, a first electrode, and a second electrode disposed in the second semiconductor layer, with a gate electrode disposed in the third gate conductive layer and overlapping the channel portion.

For example, the second semiconductor layer may include an oxide semiconductor material.

For example, the first transistor T1 may include a channel portion CH1 disposed in the second semiconductor layer, a first electrode E11 disposed in the second semiconductor layer and connected to a side of the channel portion CH1, a second electrode E21 disposed in the second semiconductor layer and connected to the other side of the channel portion CH1, and a gate electrode G1 disposed in the third gate conductive layer and overlapping the channel portion CH1.

An upper surface of the channel portion CH1 of the first transistor T1 may face the gate electrode G1.

A lower surface of the channel portion CH1 of the first transistor T1 may face a second capacitor electrode CAE2 electrically connected to the second electrode E21 of the first transistor T1.

For example, the second capacitor electrode CAE2 may be the auxiliary gate electrode of the first transistor T1.

The second transistor T2 may include a channel portion CH2 disposed in the second semiconductor layer, a first electrode E12 disposed in the second semiconductor layer and connected to a side of the channel portion CH2, a second electrode E22 disposed in the second semiconductor layer and connected to the other side of the channel portion CH2, and a gate electrode G2 disposed in the third gate conductive layer and overlapping the channel portion CH2.

The first electrode E12 of the second transistor T2 may be electrically connected to the data line DL through a data connection electrode DCE,

The data connection electrode DCE may be disposed in the first source-drain conductive layer on the second interlayer insulating layer 126 and may be electrically connected to the first electrode E12 of the second transistor T2 through a data connection hole DCH.

The data connection hole DCH may penetrate the second interlayer insulating layer 126 and the third gate insulating layer 125.

The data line DL may be disposed in the second source-drain conductive layer on the first planarization layer 127 and may be electrically connected to the data connection electrode DCE through an auxiliary data connection hole DCAH penetrating the first planarization layer 127.

The second electrode E22 of the second transistor T2 may be electrically connected to the gate electrode G1 of the first transistor T1 through a first node connection electrode NCE1.

The first node connection electrode NCE1 may be disposed in the first source-drain conductive layer on the second interlayer insulating layer 126.

The first node connection electrode NCE1 may be electrically connected to the gate electrode G1 of the first transistor T1 through a first node connection hole NCH1, electrically connected to a first capacitor electrode CAE1 through a second node connection hole NCH2, and electrically connected to the second electrode E22 of the second transistor T2 through a third node connection hole NCH3.

The first capacitor electrode CAE1 may be disposed in the first gate conductive layer on the first gate insulating layer 122.

The second electrode E21 of the first transistor T1 may be electrically connected to the first electrode E16 of the sixth transistor T6 through a second node connection electrode NCE2.

The second node connection electrode NCE2 may be disposed in the first source-drain conductive layer on the second interlayer insulating layer 126.

The second node connection electrode NCE2 may be electrically connected to the second electrode E21 of the first transistor T1 through a fourth node connection hole NCH4, electrically connected to a second capacitor electrode CAE2 through a fifth node connection hole NCH5, and electrically connected to the first electrode E16 of the sixth transistor T6 through a sixth node connection hole NCH6.

The second capacitor electrode CAE2 may be disposed in the second gate conductive layer on the second gate insulating layer 123.

Since the first capacitor electrode CAE1 is electrically connected to the gate electrode G1 of the first transistor T1 and the second capacitor electrode CAE2 is electrically connected to the second electrode E21 of the first transistor T1, the first capacitor C1 may be provided by an area where the first capacitor electrode CAE1 and the second capacitor electrode CAE2 overlap each other.

The first power line VDL may be disposed in the second source-drain conductive layer on the first planarization layer 127.

In order for the first power ELVDD to be applied with a relatively uniform resistance to the entire display area DA, the first power line VDL may be electrically connected to a first power auxiliary line VDAL and a first power extension line VDEL which extend in a direction intersecting the first power line VDL.

The first power auxiliary line VDAL may be disposed in the first gate conductive layer on the first gate insulating layer 122.

The first power extension line VDEL may be disposed in the first source-drain conductive layer on the second interlayer insulating layer 126.

A portion of the second capacitor electrode CAE2 may overlap the first power auxiliary line VDAL.

A portion of the first electrode E16 of the sixth transistor T6 may overlap the first power auxiliary line VDAL.

The second capacitor electrode CAE2 may be electrically connected to the gate electrode G1 of the first transistor T1 and the first electrode E16 of the sixth transistor T6.

Therefore, the second capacitor C2 may be provided by an area where each of the first electrode E16 of the sixth transistor T6 and the second capacitor electrode CAE2 overlaps the first power auxiliary line VDAL.

The second electrode E26 of the sixth transistor T6 may be electrically connected to an anode 131 of the light emitting element LE through a first anode connection electrode ANCE1 and a second anode connection electrode ANCE2.

The first anode connection electrode ANCE1 may be disposed in the first source-drain conductive layer on the second interlayer insulating layer 126 and may be electrically connected to the second electrode E26 of the sixth transistor T6 through a first anode contact hole ANCH1.

The first anode contact hole ANCH1 may penetrate the second interlayer insulating layer 126, the third gate insulating layer 125, the first interlayer insulating layer 124, the second gate insulating layer 123, and the first gate insulating layer 122.

The second anode connection electrode ANCE2 may be disposed in the second source-drain conductive layer on the first planarization layer 127 and may be electrically connected to the first anode connection electrode ANCE1 through a second anode contact hole ANCH2 penetrating the first planarization layer 127.

The anode 131 may be disposed on the second planarization layer 128 and may be electrically connected to the second anode connection electrode ANCE2 through a third anode contact hole ANCH3 penetrating the second planarization layer 128.

The element layer 130 may be disposed on the circuit layer 120 and may include the light emitting elements LE corresponding to the emission areas EA.

Each of the light emitting elements LE may include the anode 131 and a cathode 134 facing each other, with a light emitting layer 133 disposed between them.

For example, the element layer 130 may include the anodes 131 disposed in the emission areas EA, a pixel defining layer 132 disposed in the non-emission area and covering edges of the anodes 131, the light emitting layers 133 disposed on the anodes 131, and the cathode 134 disposed on the light emitting layers 133 and the pixel defining layer 132.

The pixel defining layer 132 may include a first pixel defining layer 1321 disposed on the second planarization layer 128, a second pixel defining layer 1322 disposed on the first pixel defining layer 1321, and a spacer layer 1323 disposed on a portion of the second pixel defining layer 1322.

For example, the first pixel defining layer 1321 may include a light-absorbing insulating material that absorbs light or a light-blocking insulating material that blocks light,

In another embodiment, each of the light emitting elements LE may further include a first common layer disposed between the anode 131 and the light emitting layer 133, and a second common layer disposed between the light emitting layer 133 and the cathode 134.

The anode 131 may be disposed in each of the emission areas EA and may be electrically connected to a light-emitting pixel driver EPD of the circuit layer 120. The anode 131 may also be referred to as a pixel electrode.

The light emitting layer 133 may include an organic light emitting material that converts electron-hole pairs into light.

The cathode 134 may be disposed in the display area DA including the emission areas EA. The second power ELVSS (see FIG. 5) may be commonly applied to the cathode 134. The cathode 134 may also be referred to as a common electrode.

The sealing layer 140 may be disposed on the circuit layer 120 and may cover the element layer 130.

For example, the sealing layer 140 may include a first sealing layer disposed on the element layer 130 and made of an inorganic insulating material, a second sealing layer disposed on the first scaling layer, overlapping the element layer 130, and made of an organic insulating material, and a third sealing layer disposed on the first sealing layer, covering the second sealing layer, and made of an inorganic insulating material.

FIG. 7 is a schematic plan view of the substrate 110 of FIG. 3 according to embodiments.

Referring to FIG. 7, the substrate 110 of the display device 100 according to the embodiments includes the main area MA corresponding to the display surface and the sub-area SBA protruding from a portion of a side of the main area MA.

The main area MA includes the display area DA disposed primarily in the center and the non-display area NDA disposed at edges and surrounding the display area DA.

The display area DA may include a bypass area BYA disposed on a side adjacent to the sub-area SBA and a general area GA disposed in an area other than the bypass area BYA.

The bypass area BYA may include a bypass middle area BMA disposed in the middle in the first direction DR1, a first bypass side area BSA1 disposed side by side with the bypass middle area BMA in the first direction DR1 and contacting the non-display area NDA, and a second bypass side area BSA2 disposed between the bypass middle area BMA and the first bypass side area BSA1.

The first bypass side area BSA1 may be disposed closer to corners of the substrate 110 than the bypass middle area BMA and the second bypass side area BSA2.

The first bypass side area BSA1 and the second bypass side area BSA2 may be disposed between each of both sides of the bypass middle area BMA in the first direction DR1 and the non-display area NDA.

The general area GA may include a general middle area GMA connected to the bypass middle area BMA of the bypass area BYA in the second direction DR2, a first general side area GSA1 connected to the first bypass side area BSA1 of the bypass area BYA in the second direction DR2, and a second general side area GSA2 connected to the second bypass side area BSA2 of the bypass area BYA in the second direction DR2.

The non-display area NDA may include a gate driving circuit area GDRA in which a gate driving circuit is disposed.

The gate driving circuit area GDRA in the non-display area NDA may face a side of the display area DA which extends in the second direction DR2. However, this is merely an example, and the gate driving circuit area GDRA may also be separated and disposed in parts of the display area DA rather than in the non-display area NDA.

The gate driving circuit of the gate driving circuit area GDRA may sequentially transmit gate signals to gate lines. The gate lines may include a scan write line GWL (see FIG. 5) which transmits a scan write signal GW (see FIG. 5), a reset control line GRL (see FIG. 5) which transmits a reset control signal GR (see FIG. 5), a bias control line GBL (see FIG. 5) which transmits a bias control signal GB (see FIG. 5), a first emission control line ECL1 (see FIG. 5) which transmits a first emission control signal EC1 (see FIG. 5), and a second emission control line ECL2 (see FIG. 5) which transmits a second emission control signal EC2 (see FIG. 5).

The sub-area SBA may include the bending area BA transformed into a bent shape, the first sub-area SB1 disposed between a side of the bending area BA and the main area MA, and the second sub-area SB2 connected to the other side of the bending area BA.

In the case where the bending area BA is transformed into a bent shape, the second sub-area SB2 may be placed under the substrate 110 and overlapped by the main area MA.

The display driving circuit 200 may be disposed in the second sub-area SB2.

Signal pads SPD bonded to the circuit board 300 (see FIG. 3) may be disposed on an edge of the second sub-area SB2.

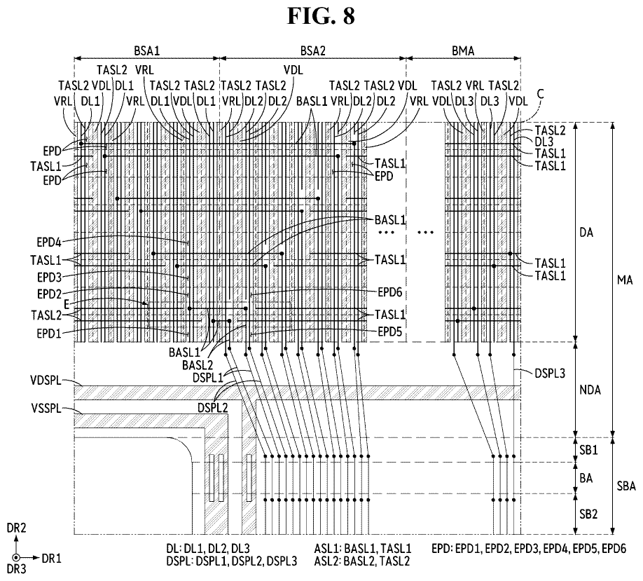

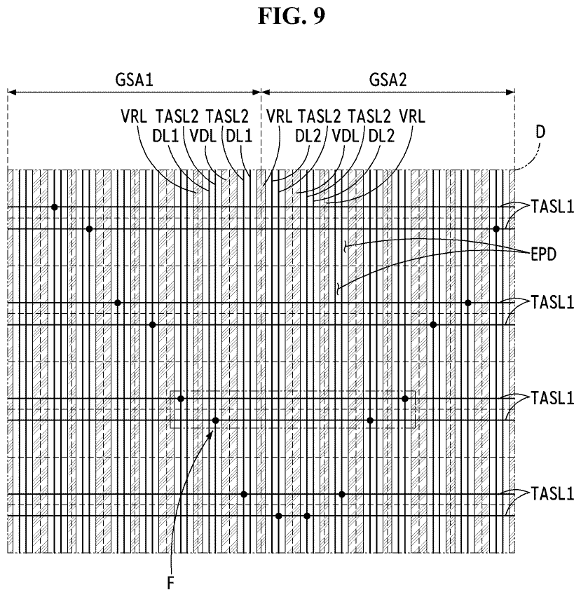

FIG. 8 is a schematic layout view of the circuit layer 120 in part C of FIG. 7. FIG. 9 is a schematic layout view of the circuit layer 120 in part D of FIG. 7.

Referring to FIGS. 8 and 9, the circuit layer 120 (see FIG. 3) of the display device 100 according to the embodiments may include light-emitting pixel drivers EPD electrically connected to the light emitting elements LE (see FIG. 5) of the element layer 130 (see FIG. 3), and disposed side by side in the first direction DR1 and the second direction DR2, data lines DL extending in the second direction DR2 and transmitting data signals Vdata (see FIG. 5) to the light-emitting pixel drivers EPD, first auxiliary lines ASL1 extending in the first direction DR1, and second auxiliary lines ASL2 extending in the second direction DR2 and neighboring the data lines DL.

The first auxiliary lines ASL1 may include first bypass auxiliary lines BASL1 electrically connected to first data lines DL1 adjacent to the non-display area NDA in the first direction DR1 among the data lines DL and first transmission auxiliary lines TASL1 other than the first bypass auxiliary lines BASL1.

The second auxiliary lines ASL2 may include second bypass auxiliary lines BASL2 electrically connected to the first bypass auxiliary lines BASL1 and second transmission auxiliary lines TASL2 other than the second bypass auxiliary lines BASL2.

The second bypass auxiliary lines BASL2 may neighbor second data lines DL2 spaced farther from the non-display area NDA than the first data lines DL1 in the first direction DR1 among the data lines DL.

The first data lines DL1 may be disposed in the first bypass side area BSA1.

The second data lines DL2 and the second bypass auxiliary lines BASL2 may be disposed in the second bypass side area BSA2.

The first bypass auxiliary lines BASL1 may be disposed in the first bypass side area BSA1 and the second bypass side area BSA2.

The data lines DL may include the first data lines DL1 disposed in the first bypass side area BSA1 and the second data lines DL2 disposed in the second bypass side area BSA2.

According to embodiments, the circuit layer 120 may further include data supply lines DSPL disposed in the non-display area NDA and electrically connected between the display driving circuit 200 and the data lines DL.

The data supply lines DSPL may extend to the bypass middle area BMA and the second bypass side area BSA2.

The data supply lines DSPL may include first data supply lines DSPL1 which transmit data signals of the first data lines DL1 and second data supply lines DSPL2 which transmit data signals of the second data lines DL2.

The first data supply lines DSPL1 may extend to the second bypass auxiliary lines BASL2 of the second bypass side area BSA2 and may be electrically connected to the first data lines DL1 through the second bypass auxiliary lines BASL2 and the first bypass auxiliary lines BASL1.

The second data supply lines DSPL2 may extend to the second bypass side area BSA2 and may be directly connected and/or electrically connected to the second data lines DL2.

Since the first data supply lines DSPL1 extend to the second bypass auxiliary lines BASL2 of the second bypass side area BSA2 rather than to the first data lines DL1 of the first bypass side area BSA1 as described above, a length by which the first data supply lines DSPL1 extend may be reduced. Accordingly, a width of an area required for the placement of the data supply lines DSPL may be reduced, thus reducing a width of the non-display area NDA.

Since the data supply lines DSPL are not disposed in a part of the non-display area NDA which is adjacent to a corner of the substrate 110, the width of the non-display area NDA can be further reduced.

The data lines DL may further include third data lines DL3 disposed in the bypass middle area BMA. The data supply lines DSPL may further include third data supply lines DSPL3 which transmit data signals of the third data lines DL3.

The third data supply lines DSPL3 may extend to the bypass middle area BMA and may be directly connected and/or electrically connected to the third data lines DL3.

The first bypass auxiliary lines BASL1 may be disposed between the first data lines DL1 and the second bypass auxiliary lines BASL2.

The second bypass auxiliary lines BASL2 may be disposed between the first data supply lines DSPL1 of the non-display area NDA and the first bypass auxiliary lines BASL1.

Since the first bypass auxiliary lines BASL1 and the second bypass auxiliary lines BASL2 are disposed only in the bypass area BYA and ends of the first bypass auxiliary lines BASL1 and ends of the second bypass auxiliary lines BASL2 are disposed in the display area DA as described above, the visibility of the first bypass auxiliary lines BASL1 and the second bypass auxiliary lines BASL2 may be increased.

To prevent this, the first auxiliary lines ASL1 may further include the first transmission auxiliary lines TASL1 in addition to the first bypass auxiliary lines BASL1. The second auxiliary lines ASL2 may further include the second transmission auxiliary lines TASL2 in addition to the second bypass auxiliary lines BASL2.

Two of the first transmission auxiliary lines TASL1 may extend from both ends of a first bypass auxiliary line BASL1 to the non-display area NDA.

One of the second transmission auxiliary lines TASL2 may extend from an end of a second bypass auxiliary line BASL2 to the non-display area NDA in a direction away from the sub-area SBA.

Since the second bypass auxiliary lines BASL2 are disposed only in the second bypass side area BSA2, each of the first data lines DL1 of the first bypass side area BSA1 and the third data lines DL3 of the bypass middle area BMA may neighbor the second transmission auxiliary lines TASL2.

According to embodiments, each of the first transmission auxiliary lines TASL1 and the second transmission auxiliary lines TASL2 may be electrically connected to one of a first power line VDL (see FIG. 5) which transmits first power ELVDD (see FIG. 5), a second power line which transmits second power ELVSS (see FIG. 5), an initialization voltage line VAIL (see FIG. 5) which transmits an initialization voltage VAINT (see FIG. 5), and a reference voltage line VRL (see FIG. 5) which transmits a reference voltage VREF (see FIG. 5). The resistance of a path through which power or a constant voltage is transmitted can be lowered by the first transmission auxiliary lines TASL1 and the second transmission auxiliary lines TASL2.

According to embodiments, the circuit layer 120 may further include a first power supply line VDSPL and a second power supply line VSSPL disposed in the non-display area NDA and extending to the sub-area SBA.

The first power supply line VDSPL may transmit the first power ELVDD (see FIG. 5), and the second power supply line VSSPL may transmit the second power ELVSS (see FIG. 5).

The first power supply line VDSPL may be electrically connected to a first power pad for transmitting the first power ELVDD (see FIG. 5) among the signal pads SPD (see FIG. 7) disposed in the second sub-area SB2.

The second power supply line VSSPL (see FIG. 5) may be electrically connected to a second power pad for transmitting the second power ELVSS (see FIG. 5) among the signal pads SPD (see FIG. 7) disposed in the second sub-area SB2.

For example, at least some of the first transmission auxiliary lines TASL1 may be electrically connected to the second power supply line VSSPL.

At least some of the second transmission auxiliary lines TASL2 may be electrically connected to at least some of the first transmission auxiliary lines TASL1 and the second power supply line VSSPL.

According to embodiments, the circuit layer 120 may further include first power lines VDL which transmit the first power ELVDD (see FIG. 5) to the light-emitting pixel drivers EPD.

The first power lines VDL may extend in the second direction DR2 and may be electrically connected to the first power supply line VDSPL.

Each of the first power lines VDL may be disposed between two second auxiliary lines ASL2 adjacent to each other in the first direction DR1.

According to embodiments, the circuit layer 120 may further include reference voltage lines VRL which transmit the reference voltage VREF (see FIG. 5) to the light-emitting pixel drivers EPD.

The reference voltage lines VRL may extend in the second direction DR2.

Each of the reference voltage lines VRL may be disposed between two data lines DL adjacent to each other in the first direction DR1.

Referring to FIG. 9, the first transmission auxiliary lines TASL1 among the first auxiliary lines ASL1 and the second transmission auxiliary lines TASL2 among the second auxiliary lines ASL2 may be disposed in the general area GA.

Each of the first transmission auxiliary lines TASL1 may be electrically connected to at least some of the second transmission auxiliary lines TASL2.

As illustrated in FIGS. 8 and 9, according to embodiments, two of the first auxiliary lines ASL1 may be disposed adjacent to a boundary between two light-emitting pixel drivers EPD neighboring each other in the second direction DR2.

As illustrated in FIG. 8, the light-emitting pixel drivers EPD may include a first light-emitting pixel driver EPD1, a second light-emitting pixel driver EPD2, a third light-emitting pixel driver EPD3, and a fourth light-emitting pixel driver EPD4, disposed side by side in the second direction DR2 and overlapping a first data line DL1, and a fifth light-emitting pixel driver EPD5 and a sixth light-emitting pixel driver EPD6 neighboring each other in the second direction DR2 and overlapping a second data line DL2.

The fifth light-emitting pixel driver EPD5 may be disposed side by side with the first light-emitting pixel driver EPD1 in the first direction DR1, and the sixth light-emitting pixel driver EPD6 may be disposed side by side with the second light-emitting pixel driver EPD2 in the first direction DR1.

The first auxiliary lines ASL1 may include two adjacent first auxiliary lines ASL1 adjacent to a boundary between the first light-emitting pixel driver EPD1 and the second light-emitting pixel driver EPD2 and a boundary between the fifth light-emitting pixel driver EPD5 and the sixth light-emitting pixel driver EPD6.

For example, any two first bypass auxiliary lines BASL1 among the first auxiliary lines ASL1 may be adjacent to the boundary between the first light-emitting pixel driver EPD1 and the second light-emitting pixel driver EPD2 and the boundary between the fifth light-emitting pixel driver EPD5 and the sixth light-emitting pixel driver EPD6.

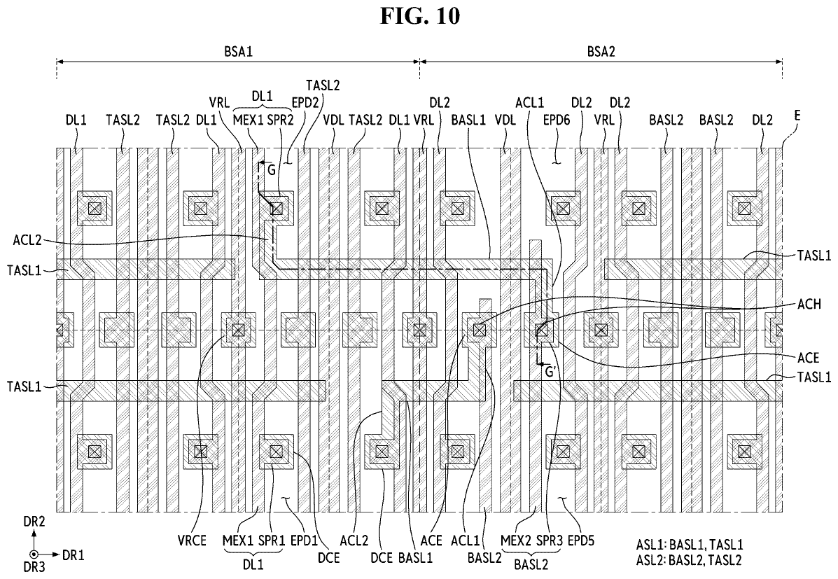

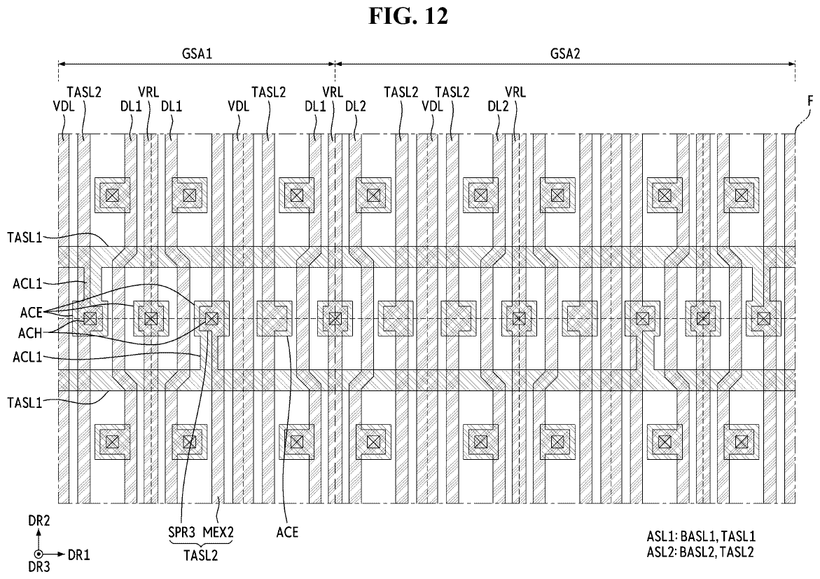

FIG. 10 is a schematic plan view of part E of FIG. 8 according to an embodiment, FIG, 11 is a schematic cross-sectional view taken along line G-G′ of FIG. 10. FIG. 12 is a schematic plan view of part F of FIG. 9 according to an embodiment.

As illustrated in FIGS. 10 and 12, the circuit layer 120 of the display device 100 according to the embodiments may include auxiliary connection electrodes ACE disposed between two adjacent first auxiliary lines ASL1 among the first auxiliary lines ASL1 and spaced apart from the two adjacent first auxiliary lines ASL1.

As illustrated in FIG. 10, when two adjacent first auxiliary lines ASL1 are adjacent to the boundary between the first light-emitting pixel driver EPD1 and the second light-emitting pixel driver EPD2, and the boundary between the fifth light-emitting pixel driver EPD5 and the sixth light-emitting pixel driver EPD6, one auxiliary connection electrode ACE among the auxiliary connection electrodes ACE disposed between the two adjacent first auxiliary lines ASL1 may overlap the boundary between the first light-emitting pixel driver EPD1 and the second light-emitting pixel driver EPD2. Another auxiliary connection electrode ACE among the auxiliary connection electrodes ACE disposed between the two adjacent first auxiliary lines ASL1 may overlap the boundary between the fifth light-emitting pixel driver EPD5 and the sixth light-emitting pixel driver EPD6.

According to embodiments, any one of the first data lines DL1 disposed in the first bypass side area BSA1 may overlap the first light-emitting pixel driver EPD1 and the second light-emitting pixel driver EPD2.

The first data line DL1 overlapping the first light-emitting pixel driver EPD1 and the second light-emitting pixel driver EPD2 may include a first main extension portion MEX1 extending in the second direction DR2, a first sub-protruding portion SPR1 protruding from the first main extension portion MEX1 and overlapping the first light-emitting pixel driver EPD1, and a second sub-protruding portion SPR2 protruding from the first main extension portion MEX1 and overlapping the second light-emitting pixel driver EPD2.

Each of the first sub-protruding portion SPR1 and the second sub-protruding portion SPR2 may be spaced from the one auxiliary connection electrode ACE overlapping the boundary between the first light-emitting pixel driver EPD1 and the second light-emitting pixel driver EPD2.

Each of the first sub-protruding portion SPR1 and the second sub-protruding portion SPR2 may be spaced from the two adjacent first auxiliary lines ASL1 adjacent to the boundary between the first light-emitting pixel driver EPD1 and the second light-emitting pixel driver EPD2.

According to embodiments, the circuit layer 120 may further include data connection electrodes DCE overlapping the first sub-protruding portion SPR1 and the second sub-protruding portion SPR2.

Each of the data connection electrodes DCE may be electrically connected to the first data line DL1 through an auxiliary data connection hole DCAH.

As illustrated in FIGS. 10 and 12, according to embodiments, each of the data lines DL may include the first main extension portion MEX1 and the first sub-protruding portion SPR1 and the second sub-protruding portion SPR2 which protrude from the first main extension portion MEX1 and overlap two light-emitting pixel drivers EPD neighboring each other in the second direction DR2. The first sub-protruding portion SPR1 and the second sub-protruding portion SPR2 may overlap the data connection electrodes DCE, respectively. The auxiliary data connection hole DCAH may be formed between each of the first sub-protruding portion SPR1 and the second sub-protruding portion SPR2 and a data connection electrode DCE.

As illustrated in FIG. 10, according to embodiments, any one of the second data lines DL2 disposed in the second bypass side area BSA2 may overlap the fifth light-emitting pixel driver EPD5 and the sixth light-emitting pixel driver EPD6.

One of the second auxiliary lines ASL2 may overlap the fifth light-emitting pixel driver EPD5 and the sixth light-emitting pixel driver EPD6 and may neighbor the second data line DL2.

The second auxiliary line ASL2 overlapping the fifth light-emitting pixel driver EPD5 and the sixth light-emitting pixel driver EPD6 may include a second main extension portion MEX2 extending in the second direction DR2 and a third sub-protruding portion SPR3 protruding from the second main extension portion MEX2 and overlapping the another auxiliary connection electrode ACE disposed at the boundary between the fifth light-emitting pixel driver EPD5 and the sixth light-emitting pixel driver EPD6.

The third sub-protruding portion SPR3 may be electrically connected to another auxiliary connection electrode ACE through an auxiliary connection hole ACH.

For example, as illustrated in FIGS. 10 and 12, according to embodiments, each of the second auxiliary lines ASL2 may include the second main extension portion MEX2 and the third sub-protruding portion SPR3 which protrudes from the second main extension portion MEX2 and overlaps the boundary between two light-emitting pixel drivers EPD neighboring each other in the second direction DR2. The third sub-protruding portion SPR3 may overlap an auxiliary connection electrode ACE.

According to an embodiment, the auxiliary connection hole ACH may be selectively formed between the third sub-protruding portion SPR3 and the auxiliary connection electrode ACE.

For example, according to an embodiment, the auxiliary connection hole ACH may not be formed in each of all auxiliary connection electrodes ACE, but may be selectively formed only in some auxiliary connection electrodes ACE which electrically connect the first auxiliary lines ASL1 and the second auxiliary lines ASL2.

As illustrated in FIG. 10 and FIG. 12, according to embodiments, the circuit layer 120 may further include a first auxiliary connection line ACL1 extending from one of the two adjacent first auxiliary lines ASL1 in the second direction DR2 and connected to another auxiliary connection electrode ACE.

For example, the another auxiliary connection electrode ACE overlapping the boundary between the fifth light-emitting pixel driver EPD5 and the sixth light-emitting pixel driver EPD6 may be electrically connected to one second auxiliary line ASL2 through an auxiliary connection hole ACH and may be electrically connected to one first auxiliary line ASL1 through a first auxiliary connection line ACL1.

Accordingly, the first auxiliary line ASL1 may be electrically connected to the second auxiliary line ASL2 through the first auxiliary connection line ACL1, the another auxiliary connection electrode ACE, and the auxiliary connection hole ACH.

For example, the another auxiliary connection electrode ACE overlapping the boundary between the fifth light-emitting pixel driver EPD5 and the sixth light-emitting pixel driver EPD6 may be electrically connected to one second bypass auxiliary line BASL2 through the auxiliary connection hole ACH and may be electrically connected to one first bypass auxiliary line BASL1 through the first auxiliary connection line ACL1.

Accordingly, the first bypass auxiliary line BASL1 may be electrically connected to the second bypass auxiliary line BASL2 through the first auxiliary connection line ACL1, the another auxiliary connection electrode ACE, and the auxiliary connection hole ACH.

As illustrated in FIG. 10, according to embodiments, the circuit layer 120 may further include a second auxiliary connection line ACL2 extending from one of the two adjacent first auxiliary lines ASL1 in the second direction DR2 and connected to one of the data connection electrodes DCE.

For example, one of the two data connection electrodes DCE disposed in the first light-emitting pixel driver EPD1 and the second light-emitting pixel driver EPD2 may be electrically connected to the first data line DL1 through an auxiliary data connection hole DCAH and may be electrically connected to one first auxiliary line ASL1 through a second auxiliary connection line ACL2.

Accordingly, the first auxiliary line ASL1 may be electrically connected to the first data line DL1 through the second auxiliary connection line ACL2, the data connection electrode DCE, and the auxiliary data connection hole DCAH.

According to embodiments, the circuit layer 120 may further include reference voltage connection electrode VRCE overlapping the reference voltage line VRL.

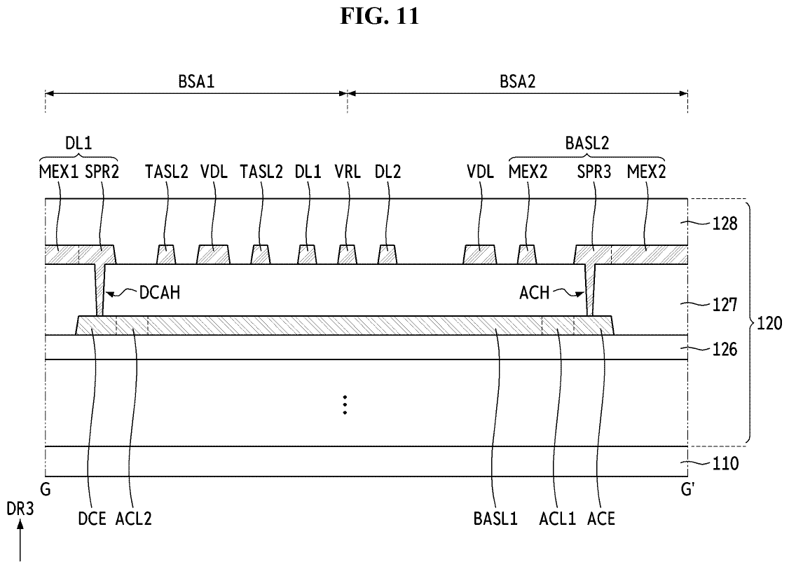

Referring to FIG. 11, the data lines DL and the second auxiliary lines ASL2 may be disposed on at least one insulating layer (i.e., the first planarization layer 127) which covers the first auxiliary lines ASL1, the auxiliary connection electrodes ACE, the data connection electrodes DCE, the first auxiliary connection line ACL1, and the second auxiliary connection line ACL2.

The first power line VDL and the reference voltage line VRL may also be disposed on at least one insulating layer (i.e., the first planarization layer 127).

For example, the data lines DL, the second auxiliary lines ASL2, the first power line VDL, and the reference voltage line VRL may be disposed in the second source-drain conductive layer on the first planarization layer 127.

The first auxiliary lines ASL1, the auxiliary connection electrodes ACE, the data connection electrodes DCE, the first auxiliary connection line ACL1, and the second auxiliary connection line ACL2 may be disposed in the first source-drain conductive layer on the second interlayer insulating layer 126.

Each of the auxiliary connection hole ACH and the auxiliary data connection hole DCAH may penetrate the first planarization layer 127.

As illustrated in FIG. 12, according to embodiments, each of the first transmission auxiliary lines TASL1 may be electrically connected to at least one second transmission auxiliary line TASL2 through a first auxiliary connection line ACL1, an auxiliary connection electrode ACE, and an auxiliary connection hole ACH.

As described above, according to embodiments, only one auxiliary connection electrode ACE is disposed between two light-emitting pixel drivers EPD neighboring each other in the second direction DR2.

Even in the case where two auxiliary connection electrodes ACE respectively corresponding to the two light-emitting pixel drivers EPD neighboring each other in the second direction DR2 are not disposed, each of a second auxiliary line ASL2 and a first data line DL1 can be electrically connected to a first auxiliary line ASL1 through selective placement of a first auxiliary connection line ACL1 and a second auxiliary connection line ACL2.

Accordingly, the total number of auxiliary connection electrodes ACE disposed in the display area DA may become half of the total number of light-emitting pixel drivers EPD, thereby improving the integration density of the light-emitting pixel drivers EPD. This may be advantageous for achieving high resolution in the display device 100.

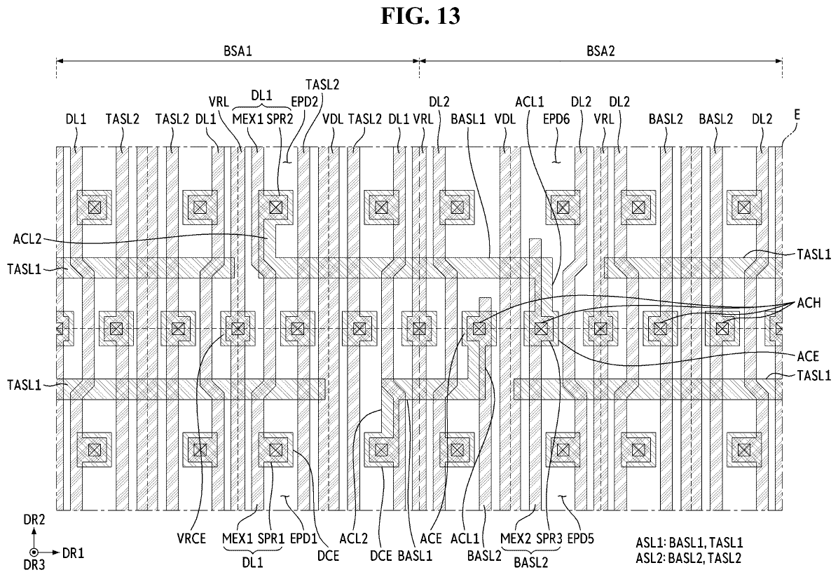

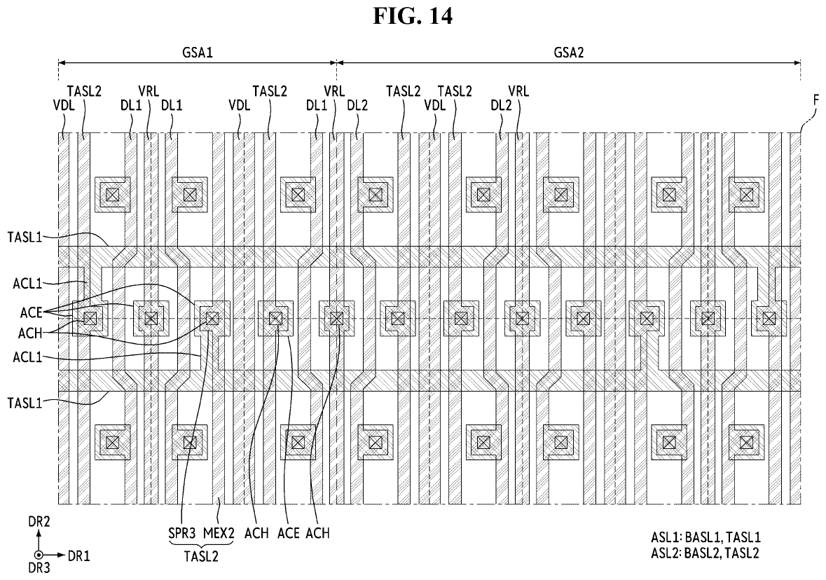

FIG. 13 is a schematic plan view of part E of FIG. 8 according to an embodiment. FIG. 14 is a schematic plan view of part F of FIG. 9 according to an embodiment.

Referring to FIGS. 13 and 14, a display device 100 according to an embodiment may be substantially the same as the display device 100 of the embodiments illustrated in FIGS. 10 through 12, except that an auxiliary connection hole ACH is formed in each of all auxiliary connection electrodes ACE, rather than being selectively formed only in some of the auxiliary connection electrodes ACE, and thus a redundant description thereof will be omitted below,

By eliminating a difference in light emission characteristics caused by the presence or absence of the auxiliary connection hole ACH, the deterioration in the display quality of the display device 100 due to the auxiliary connection hole ACH can be prevented.

The display device according to an embodiment can be applied to various electronic devices. The electronic device according to an embodiment includes the display device described above, and may further include modules or devices having additional functions in addition to the display device.

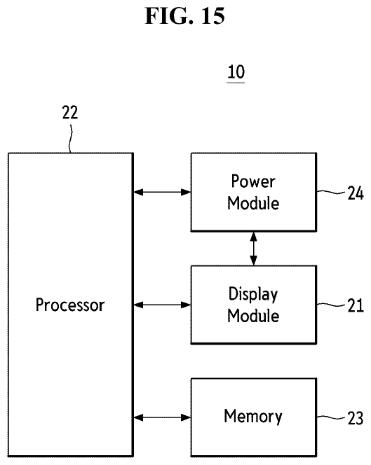

FIG. 15 is a block diagram of an electronic device according to an embodiment.

Referring to FIG. 15, the electronic device 1 according to an embodiment may include a display module 21, a processor 22, a memory 23, and a power module 24.

The processor 22 may include at least one of a central processing unit (CPU), an application processor (AP), a graphic processing unit (GPU), a communication processor (CP), an image signal processor (ISP), and a controller.

The memory 23 may store data information necessary for the operation of the processor 22 or the display module 21. When the processor 22 executes an application stored in the memory 23, an image data signal and/or an input control signal is transmitted to the display module 21, and the display module 21 can process the received signal and output image information through a display screen.

The power module 24 may include a power supply module such as, for example a power adapter or a battery, and a power conversion module that converts the power supplied by the power supply module to generate power necessary for the operation of the electronic device 1.

At least one of the components of the electronic device 10 according to an embodiment may be included in the display device 100 according to embodiments. Some modules of the individual modules functionally included in one module may be included in the display device 100, and other modules may be provided separately from the display device 100. For example, the display device 100 may include the display module 21, and the processor 22, the memory 23, and the power module 24 may be provided in the form of other devices within the electronic device 10 other than the display device 100.

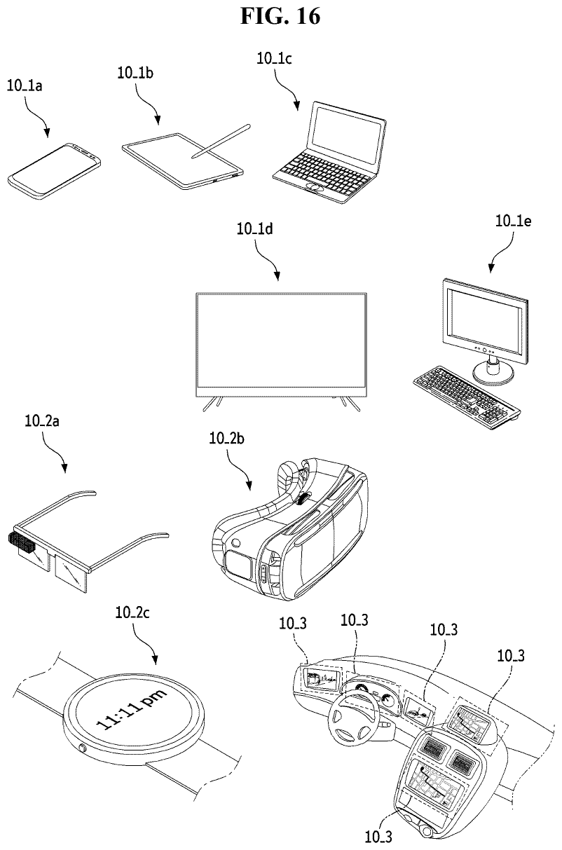

FIG. 16 is a schematic diagram of an electronic device according to embodiments.

Referring to FIG. 16, various electronic devices to which display devices 100 according to embodiments are applied may include not only image display electronic devices such as a smart phone 10_1a, a tablet PC (personal computer) 10_1b, a laptop 10_1c, a TV 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as a CID (Center Information Display) and a room mirror display arranged on a dashboard, center fascia, and dashboard of an automobile.

A display device according to embodiments may include a circuit layer and an element layer disposed on a substrate.

The element layer may include light emitting elements disposed in emission areas.

The circuit layer may include light-emitting pixel drivers electrically connected to the light emitting elements of the element layer, and arranged in a first direction and a second direction, data lines extending in the second direction and transmitting data signals to the light-emitting pixel drivers, first auxiliary lines extending in the first direction, second auxiliary lines extending in the second direction and neighboring the data lines, and auxiliary connection electrodes disposed between two adjacent first auxiliary lines among the first auxiliary lines and spaced apart from the two adjacent first auxiliary lines.

The light-emitting pixel drivers may include a first light-emitting pixel driver, a second light-emitting pixel driver, a third light-emitting pixel driver, and a fourth light-emitting pixel driver, which overlap a first data line among the data lines and are arranged side by side in the second direction. A fifth light-emitting pixel driver and a sixth light-emitting pixel driver may overlap a second data line among the data lines, be disposed side by side with the first light-emitting pixel driver and the second light-emitting pixel driver in the first direction, and neighbor each other in the second direction.

According to embodiments, the two adjacent first auxiliary lines may be adjacent to a boundary between the first light-emitting pixel driver and the second light-emitting pixel driver, as well as a boundary between the fifth light-emitting pixel driver and the sixth light-emitting pixel driver.

One auxiliary connection electrode among the auxiliary connection electrodes may overlap the boundary between the first light-emitting pixel driver and the second light-emitting pixel driver.

Another auxiliary connection electrode among the auxiliary connection electrodes may overlap the boundary between the fifth light-emitting pixel driver and the sixth light-emitting pixel driver.

According to embodiments, the circuit layer may further include a first auxiliary connection line extending in the second direction from one first auxiliary line among the two adjacent first auxiliary lines and connected to the another auxiliary connection electrode.

Therefore, in the case where another auxiliary connection electrode is electrically connected to one second auxiliary line among the second auxiliary lines through an auxiliary connection hole, the one first auxiliary line may be electrically connected to the one second auxiliary line through the first auxiliary connection line and the auxiliary connection hole.

According to embodiments, the circuit layer may further include data connection electrodes overlapping the light-emitting pixel drivers, and electrically connected to the first data line through auxiliary data connection holes, and a second auxiliary connection line extending in the second direction from the one first auxiliary line among the two adjacent first auxiliary lines and connected to one data connection electrode among the data connection electrodes.

Therefore, the one first auxiliary line may be electrically connected to the first data line through the second auxiliary connection line, the one data connection electrode, and an auxiliary data connection hole.

As described above, according to embodiments, even in the case where only one auxiliary connection electrode, instead of two auxiliary connection electrodes, is disposed at a boundary between two light-emitting pixel drivers neighboring each other in the second direction, selective electrical connection between a first auxiliary line and a second auxiliary line can be achieved through a first auxiliary connection line, and selective electrical connection between the first auxiliary line and a first data line can be achieved through a second auxiliary connection line.

Therefore, since the number of auxiliary connection electrodes can be reduced by half, the integration density of the light-emitting pixel drivers can be improved, which can be advantageous for achieving high resolution in the display device.

However, the effects of the disclosure are not restricted to those set forth herein. The above and other effects of the disclosure will become more apparent to one of ordinary skill in the art to which the disclosure pertains by referencing the claims.

Embodiments have been disclosed herein, and although terms are employed, they are used and are to be interpreted in a generic and descriptive sense only and not for purpose of limitation, In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the following claims.

What is claimed is:

1. A display device comprising:
a substrate that comprises a display area in which emission areas are arranged and a non-display area disposed around the display area;
a circuit layer disposed on the substrate; and
an element layer disposed on the circuit layer and that comprises light emitting elements disposed in the emission areas, wherein
the circuit layer comprises:
light-emitting pixel drivers that are electrically connected to the light emitting elements and are arranged in a first direction and a second direction;
data lines that extend in the second direction and transmit data signals to the light-emitting pixel drivers;
first auxiliary lines that extend in the first direction;
second auxiliary lines that extend in the second direction and neighbor the data lines; and
auxiliary connection electrodes disposed between adjacent first auxiliary lines of the first auxiliary lines and spaced apart from the adjacent first auxiliary lines.

2. The display device of claim 1, wherein
the light-emitting pixel drivers comprise:
a first light-emitting pixel driver, a second light-emitting pixel driver, a third light-emitting pixel driver, and a fourth light-emitting pixel driver that overlap a first data line of the data lines and are arranged side by side in the second direction; and
a fifth light-emitting pixel driver and a sixth light-emitting pixel driver that overlap a second data line of the data lines and are disposed side by side with the first light-emitting pixel driver and the second light-emitting pixel driver in the first direction, and neighbor each other in the second direction,
one first auxiliary line of the adjacent first auxiliary lines overlaps the first light-emitting pixel driver and the fifth light-emitting pixel driver,
another first auxiliary line of the adjacent first auxiliary lines overlaps the second light-emitting pixel driver and the sixth light-emitting pixel driver,
the adjacent first auxiliary lines are adjacent to a boundary between the first light-emitting pixel driver and the second light-emitting pixel driver, and a boundary between the fifth light-emitting pixel driver and the sixth light-emitting pixel driver,
one auxiliary connection electrode of the auxiliary connection electrodes overlaps the boundary between the first light-emitting pixel driver and the second light-emitting pixel driver, and
another auxiliary connection electrode of the auxiliary connection electrodes overlaps the boundary between the fifth light-emitting pixel driver and the sixth light-emitting pixel driver.

3. The display device of claim 2, wherein the first data line comprises:
a first main extension portion extending in the second direction;
a first sub-protruding portion protruding from the first main extension portion, overlapping the first light-emitting pixel driver, and spaced apart from the one auxiliary connection electrode; and
a second sub-protruding portion protruding from the first main extension portion, overlapping the second light-emitting pixel driver, and spaced apart from the one auxiliary connection electrode.

4. The display device of claim 3, wherein
the data lines and the second auxiliary lines are disposed on at least one insulating layer which covers the first auxiliary lines and the auxiliary connection electrodes, and
one second auxiliary line of the second auxiliary lines neighbors the second data line and overlaps the fifth light-emitting pixel driver and the sixth light-emitting pixel driver, the one second auxiliary line comprising:
a second main extension portion that extends in the second direction; and
a third sub-protruding portion that protrudes from the second main extension portion and overlaps another auxiliary connection electrode, the third sub-protruding portion being electrically connected to the another auxiliary connection electrode through an auxiliary connection hole.

5. The display device of claim 4, wherein the circuit layer further comprises a first auxiliary connection line extending in the second direction from the one first auxiliary line of the adjacent first auxiliary lines and connected to the another auxiliary connection electrode.

6. The display device of claim 5, wherein the one first auxiliary line is electrically connected to the one second auxiliary line through the first auxiliary connection line, the another auxiliary connection electrode, and the auxiliary connection hole.

7. The display device of claim 3, wherein
the circuit layer further comprises data connection electrodes overlapping the first sub-protruding portion and the second sub-protruding portion,
the data lines and the second auxiliary lines are disposed on at least one insulating layer which covers the first auxiliary lines, the auxiliary connection electrodes, and the data connection electrodes, and
each of the data connection electrodes is electrically connected to the first data line through an auxiliary data connection hole.

8. The display device of claim 7, wherein
the circuit layer further comprises a second auxiliary connection line extending in the second direction from the one first auxiliary line of the adjacent first auxiliary lines and connected to one data connection electrode of the data connection electrodes, and
the one first auxiliary line is electrically connected to the first data line through the second auxiliary connection line, the one data connection electrode, and the auxiliary data connection hole.

9. The display device of claim 3, wherein
the data lines and the second auxiliary lines are disposed on at least one insulating layer which covers the first auxiliary lines and the auxiliary connection electrodes, and
the auxiliary connection electrodes are electrically connected to the second auxiliary lines through auxiliary connection holes.

10. The display device of claim 3, wherein another adjacent first auxiliary lines of the first auxiliary lines are disposed adjacent to a boundary between the third light-emitting pixel driver and the fourth light-emitting pixel driver.

11. The display device of claim 3, further comprising:
a display driving circuit which supplies the data signals to the data lines, wherein
the circuit layer further comprises data supply lines disposed in the non-display area and electrically connected between the data lines and the display driving circuit,
a bypass area on a side of the display area comprises:
a bypass middle area,
a first bypass side area disposed side by side with the bypass middle area in the first direction and contacting the non-display area, and
a second bypass side area disposed between the bypass middle area and the first bypass side area,
the data supply lines extend to the bypass middle area and the second bypass side area,
the first data line is disposed in the first bypass side area,
the second data line is disposed in the second bypass side area,
the first auxiliary lines comprise:
a first bypass auxiliary line electrically connected to the first data line, and
first transmission auxiliary lines other than the first bypass auxiliary line, the second auxiliary lines comprise:
a second bypass auxiliary line electrically connected to the first bypass auxiliary line and neighboring the second data line, and
second transmission auxiliary lines other than the second bypass auxiliary line,
a first data supply line which transmits a data signal of the first data line of the data supply lines is electrically connected to the first data line through the first bypass auxiliary line and the second bypass auxiliary line, and
a second data supply line which transmits a data signal of the second data line of the data supply lines is directly connected and electrically connected to the second data line.

12. The display device of claim 11, wherein the circuit layer further comprises:
a first power line that transmits first power to the light-emitting pixel drivers;
a second power line that transmits second power to the light emitting elements;
a reference voltage line that transmits a reference voltage to the light-emitting pixel drivers; and
an initialization voltage line that transmits an initialization voltage to the light-emitting pixel drivers.

13. The display device of claim 12, wherein each of the first transmission auxiliary lines and the second transmission auxiliary lines is electrically connected to one of the first power line, the second power line, the reference voltage line, and the initialization voltage line.

14. The display device of claim 12, wherein each of the light-emitting pixel drivers comprises:
a first transistor;
a second transistor electrically connected between a gate electrode of the first transistor and one data line of the data lines;
a third transistor electrically connected between the gate electrode of the first transistor and the reference voltage line;
a fourth transistor electrically connected between one light emitting element of the light emitting elements and the initialization voltage line;
a fifth transistor electrically connected between a first electrode of the first transistor and the first power line;
a sixth transistor electrically connected between a second electrode of the first transistor and the one light emitting element;
a first capacitor electrically connected between the gate electrode of the first transistor and the second electrode of the first transistor; and
a second capacitor electrically connected between the first power line and the second electrode of the first transistor.

15. An electronic device comprising:
a display device displaying an image;
a memory storing an application;
a processor executing the application and transmitting an image data signal and an input control signal to the display device; and
a power supply module supplying power to the display device, wherein
the display device comprises:
a substrate comprising a display area in which emission areas are arranged and a non-display area which is disposed around the display area;
a circuit layer disposed on the substrate; and
an element layer disposed on the circuit layer and comprising light emitting elements disposed in the emission areas, wherein
the circuit layer comprises:
light-emitting pixel drivers electrically connected to the light emitting elements and arranged in a first direction and a second direction;
data lines extending in the second direction and transmitting data signals to the light-emitting pixel drivers;
first bypass auxiliary lines extending in the first direction and electrically connected to first data lines adjacent to the non-display area in the first direction of the data lines;
second bypass auxiliary lines extending in the second direction, neighboring second data lines spaced farther from the non-display area than the first data lines in the first direction of the data lines, and electrically connected to the first bypass auxiliary lines; and
auxiliary connection electrodes disposed between two first bypass auxiliary lines adjacent to each other in the second direction of the first bypass auxiliary lines and spaced apart from the two first bypass auxiliary lines.

16. The electronic device of claim 15, wherein the display device further comprises:
a display driving circuit which supplies data signals to the data lines, wherein
the circuit layer further comprises data supply lines disposed in the non-display area and electrically connected between the data lines and the display driving circuit, and
a bypass area on a side of the display area comprises:
a bypass middle area,
a first bypass side area disposed side by side with the bypass middle area in the first direction and contacting the non-display area, and
a second bypass side area disposed between the bypass middle area and the first bypass side area,
the data supply lines extend to the bypass middle area and the second bypass side area,
the first data lines are disposed in the first bypass side area,
the second data lines and the second bypass auxiliary lines are disposed in the second bypass side area,
first data supply lines which transmit data signals of the first data lines of the data supply lines are electrically connected to the first data lines through the first bypass auxiliary lines and the second bypass auxiliary lines, and
second data supply lines which transmit data signals of the second data lines of the data supply lines are directly connected and electrically connected to the second data lines.

17. The electronic device of claim 16, wherein
the light-emitting pixel drivers comprise:
a first light-emitting pixel driver, a second light-emitting pixel driver, a third light-emitting pixel driver, and a fourth light-emitting pixel driver disposed in the first bypass side area, overlapping one first data line of the first data lines, and arranged side by side in the second direction; and
a fifth light-emitting pixel driver and a sixth light-emitting pixel driver disposed in the second bypass side area, overlapping one second data line of the second data lines and one second bypass auxiliary line of the second bypass auxiliary lines, and neighboring each other in the second direction,
the fifth light-emitting pixel driver and the sixth light-emitting pixel driver are disposed side by side with the first light-emitting pixel driver and the second light-emitting pixel driver in the first direction,
one first bypass auxiliary line of the two first bypass auxiliary lines overlaps the first light-emitting pixel driver and the fifth light-emitting pixel driver,
another first bypass auxiliary line of the two first bypass auxiliary lines overlaps the second light-emitting pixel driver and the sixth light-emitting pixel driver,
the two first bypass auxiliary lines are adjacent to a boundary between the first light-emitting pixel driver and the second light-emitting pixel driver and a boundary between the fifth light-emitting pixel driver and the sixth light-emitting pixel driver,
one auxiliary connection electrode of the auxiliary connection electrodes overlaps the boundary between the first light-emitting pixel driver and the second light-emitting pixel driver, and
another auxiliary connection electrode of the auxiliary connection electrodes overlaps the boundary between the fifth light-emitting pixel driver and the sixth light-emitting pixel driver.

18. The electronic device of claim 17, wherein
the data lines and the second bypass auxiliary lines are disposed on at least one insulating layer which covers the first auxiliary lines,
the one first data line comprises:
a first main extension portion extending in the second direction,
a first sub-protruding portion protruding from the first main extension portion, overlapping the first light-emitting pixel driver and spaced apart from the one auxiliary connection electrode, and
a second sub-protruding portion protruding from the first main extension portion, overlapping the second light-emitting pixel driver and spaced apart from the one auxiliary connection electrode, and
the one second bypass auxiliary line comprises:
a second main extension portion extending in the second direction, and
a third sub-protruding portion protruding from the second main extension portion and overlapping another auxiliary connection electrode, wherein
the third sub-protruding portion is electrically connected to the another auxiliary connection electrode through an auxiliary connection hole.

19. The electronic device of claim 18, wherein
the circuit layer further comprises a first auxiliary connection line extending in the second direction from the one first bypass auxiliary line of the two first bypass auxiliary lines and connected to the another auxiliary connection electrode, and
the one first bypass auxiliary line is electrically connected to the one second bypass auxiliary line through the first auxiliary connection line, the another auxiliary connection electrode, and the auxiliary connection hole.

20. The electronic device of claim 18, wherein the circuit layer further comprises:
data connection electrodes overlapping the first sub-protruding portion and the second sub-protruding portion and electrically connected to the one first data line through an auxiliary data connection hole; and
a second auxiliary connection line extending from the one first bypass auxiliary line in the second direction and connected to one data connection electrode of the data connection electrodes, wherein
the one first bypass auxiliary line is electrically connected to the one first data line through the second auxiliary connection line, the one data connection electrode, and the auxiliary data connection hole.
